(19) United States
(12) Patent Application Publication
(10) Pub. No.: US 2025/0285908 A1
(43) Pub. Date: Sep. 11, 2025

(54) WAFER MOUNTING APPARATUS, SEMICONDUCTOR MANUFACTURING APPARATUS, METHOD OF MANUFACTURING SEMICONDUCTOR DEVICE, AND SEMICONDUCTOR DEVICE

(71) Applicant: Mitsubishi Electric Corporation, Tokyo (JP)

(72) Inventor: Yoichiro NISHIMOTO, Tokyo (JP)

(73) Assignee: Mitsubishi Electric Corporation, Tokyo (JP)

(21) Appl. No.: 18/960,522

(22) Filed: Nov. 26, 2024

(30) Foreign Application Priority Data
Mar. 8, 2024 (JP) 2024-035803

(51) Int. Cl. H01L 21/687; H01L 21/02; H01L 21/67

(52) U.S. Cl. CPC H01L 21/68742; H01L 21/67098; H01L 21/68785; H01L 21/02293

(57) ABSTRACT

A ring is mounted on a satellite disk in such a manner that a terrace portion is supported by a peripheral portion front surface of a peripheral portion of the satellite disk. A SiC wafer is mounted on three lift-up pins mounted on a front surface of the terrace portion. A disk upper space is formed between a front surface of an upper layer portion of the satellite disk and a back surface of the SiC wafer. A wall portion of the ring is disposed to face an orientation flat portion via a gap space. On the back surface side of the SiC wafer, an annular groove is formed along an outer periphery of an opening in plan view, and one side surface of the groove is a side surface of the upper layer portion.

### BACKGROUND OF THE INVENTION

### Field of the Invention

The present disclosure relates to a wafer mounting apparatus for mounting a semiconductor wafer, typified by a susceptor used for epitaxial growth of a SiC film on a SiC single crystal wafer.

### Description of the Background Art

A susceptor used for epitaxial growth of a SiC film on a SiC single crystal wafer is generally used as a conventional wafer mounting apparatus. A conventional susceptor is disclosed in, for example, Japanese Patent Application Laid-Open No. 2016-119472.

Japanese Patent Application Laid-Open No. 2016-119472 is characterized by a technique in which a step between an upper surface of a susceptor and an upper surface of a silicon wafer is set to 1 mm or more, and by using a susceptor having this characteristic, an epi-crown phenomenon described later is suppressed. Further, Japanese Patent Application Laid-Open No. 2014-27006 or Japanese Patent Application Laid-Open No. 7-226349 (1995) also discloses a conventional technique for suppressing the epi-crown phenomenon.

As a technique developed from a wafer mounting apparatus typified by a susceptor, a SiC epitaxial growth apparatus, which is a semiconductor manufacturing apparatus including the wafer mounting apparatus, can be considered. Furthermore, a method of manufacturing a semiconductor device using a SiC epitaxial growth apparatus and a semiconductor device manufactured by the method of manufacturing a semiconductor device are conceivable.

When an epitaxial layer is formed on a front surface of a semiconductor wafer such as a silicon wafer, there is a wafer susceptor top distance indicating a length in a height direction between the upper surface of the susceptor and the front surface of the semiconductor wafer as an index related to the film thickness of the epitaxial layer. When the wafer susceptor top distance is set to be relatively large, the epi thickness, which is the film thickness of the epitaxial layer, is affected in a peripheral region to be an outermost peripheral portion of the semiconductor wafer, and in-plane uniformity of the epi thickness is deteriorated.

### SUMMARY

The present disclosure has been made to solve the above-described problems, and an object of the present disclosure is to obtain a wafer mounting apparatus that improves in-plane uniformity in an epitaxial layer formed on a front surface of a semiconductor wafer.

A wafer mounting apparatus according to the present disclosure is a wafer mounting apparatus that mounts a semiconductor wafer having a cutout portion, and includes a disk, a ring, and a plurality of lift-up members.

The disk has a convex upper layer portion.

The ring is disposed on the disk and has an opening in the center.

The plurality of lift-up members is arranged on a lift-up region provided on the disk or the ring, and support the semiconductor wafer from a back surface.

The ring has a cutout-side protruding wall portion protruding toward the opening.

A semiconductor wafer mounting state is a state in which the semiconductor wafer is mounted on the plurality of lift-up members so that the semiconductor wafer fits in the opening in plan view without being in contact with the ring.

In the wafer mounting state, the cutout-side protruding wall portion faces the cutout portion of the semiconductor wafer, and a disk upper space is formed between a front surface of the upper layer portion of the disk and a back surface of the semiconductor wafer except for a formation region of the plurality of lift-up members.

In the wafer mounting state, an annular groove having an annular shape is formed along an outer periphery of the opening in plan view between the upper layer portion of the disk and the ring on a side of the back surface of the semiconductor wafer.

In the wafer mounting state, a side surface of the upper layer portion of the disk is a side surface of the annular groove.

The wafer mounting apparatus of the present disclosure can provide a disk upper space between the back surface of the semiconductor wafer and the front surface of the disk during the semiconductor wafer mounting state.

Furthermore, in the wafer mounting apparatus of the present disclosure, during the semiconductor wafer mounting state, an annular groove having an annular shape is formed between the upper layer portion of the disk and the ring on the back surface side of the semiconductor wafer, and a side surface of the upper layer portion of the disk is a side surface of the annular groove.

Therefore, when the source gas is supplied above the front surface of the semiconductor wafer in the semiconductor wafer mounting state, a part of the source gas can be intentionally released to the disk upper space on the back surface side of the semiconductor wafer via the annular groove.

Therefore, when an epitaxial layer is formed on the front surface of the semiconductor wafer in the semiconductor wafer mounting state by an epitaxial growth process, it is possible to suppress the occurrence of the epi-crown phenomenon in which the epi thickness, which is the film thickness of the epitaxial growth layer, locally increases.

As a result, the wafer mounting apparatus of the present disclosure has an effect of being able to form an epitaxial layer having an epi thickness with excellent in-plane uniformity on the front surface of the semiconductor wafer in the semiconductor wafer mounting state.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is an explanatory view schematically illustrating a planar configuration of a susceptor which is a basic configuration of a first preferred embodiment;

FIG. 2 is an explanatory view schematically illustrating a configuration of an A1-A1 cross section of FIG. 1;

FIG. 3 is an explanatory view schematically illustrating a configuration of a B1-B1 cross section of FIG. 1;

FIG. 4 is an explanatory view schematically illustrating a configuration of a C1-C1 cross section in FIG. 1;

FIG. 5 is an explanatory view illustrating an enlarged cross-sectional configuration of FIG. 2;

FIG. 6 is an explanatory view schematically illustrating a planar configuration of a susceptor which is a first modification of the first preferred embodiment;

FIG. 7 is an explanatory view schematically illustrating a configuration of a cross section taken along line A11-A11 in FIG. 6;

FIG. 8 is an explanatory view schematically illustrating a configuration of a cross section taken along line B11-B11 in FIG. 6;

FIG. 9 is an explanatory view schematically illustrating a configuration of a cross section taken along line C11 to C11 in FIG. 6;

FIG. 10 is an explanatory view schematically illustrating a planar configuration of a susceptor which is a second modification of the first preferred embodiment;

FIG. 11 is an explanatory view schematically illustrating a configuration of a cross section taken along line A12-A12 in FIG. 10;

FIG. 12 is an explanatory view schematically illustrating a configuration of a cross section taken along line B12-B12 in FIG. 10;

FIG. 13 is an explanatory view schematically illustrating a configuration of a cross section taken along line C12-C12 in FIG. 10;

FIG. 14 is an explanatory view schematically illustrating a planar configuration of a susceptor which is a basic configuration of a second preferred embodiment;

FIG. 15 is an explanatory view schematically illustrating a configuration of an A2-A2 cross section in FIG. 14;

FIG. 16 is an explanatory view schematically illustrating a configuration of a B2-B2 cross section of FIG. 14;

FIG. 17 is an enlarged explanatory view illustrating a focused region R2 in FIG. 14;

FIG. 18 is an explanatory view schematically illustrating a planar configuration of a susceptor as a basic configuration of a third preferred embodiment;

FIG. 19 is an explanatory view schematically illustrating a configuration of an A3-A3 cross section of FIG. 18;

FIG. 20 is an explanatory view schematically illustrating a configuration of a B4-B4 cross section in FIG. 18;

FIG. 21 is an explanatory view schematically illustrating a configuration of a C4-C4 cross section in FIG. 18;

FIG. 22 is an explanatory view schematically illustrating a planar configuration of a susceptor which is a basic configuration of a fourth preferred embodiment;

FIG. 23 is an explanatory view schematically illustrating a configuration of an A4-A4 cross section in FIG. 22;

FIG. 24 is an explanatory view schematically illustrating a configuration of a B4-B4 cross section in FIG. 22;

FIG. 25 is an explanatory view schematically illustrating a cross-sectional structure of a semiconductor manufacturing apparatus including a susceptor used in a preferred embodiment of the present disclosure;

FIG. 26 is an explanatory view schematically illustrating a planar configuration of the semiconductor manufacturing apparatus;

FIG. 27 is a flowchart illustrating a processing procedure of a method of manufacturing a semiconductor device using a semiconductor manufacturing apparatus;

FIG. 28 is a cross-sectional view illustrating a cross-sectional structure of a semiconductor device manufactured by the method of manufacturing a semiconductor device;

FIG. 29 is an explanatory view schematically illustrating an epi-crown phenomenon;

FIGS. 30A and 30B are explanatory views schematically illustrating a conventional susceptor;

FIG. 31 is a graph illustrating an epi-crown height when an epitaxial layer is grown using the susceptor illustrated in FIGS. 30A and 30B;

FIG. 32 is a diagram schematically illustrating a relationship between a measurement point and a reference point on a front surface of a SiC wafer;

FIG. 33 is a graph illustrating the correlation of a height of the epi-crown at an OF center portion when a wafer susceptor top distance is changed;

FIG. 34 is a graph illustrating a correlation between an average epi thickness of a wafer outer peripheral portion and the wafer susceptor top distance;

FIG. 35 is a graph illustrating an epi thickness when a wafer susceptor top distance is 0.7 mm;

FIG. 36 is a graph illustrating an epi thickness when a wafer susceptor top distance is 2.5 mm;

FIG. 37 is an explanatory view schematically illustrating a planar configuration of a conventional susceptor;

FIG. 38 is a graph illustrating an example of an epi-crown height when an epitaxial layer is formed on a front surface of a semiconductor wafer using the susceptor illustrated in FIG. 37;

FIG. 39 is an explanatory diagram illustrating a fluid simulation result regarding a fluid velocity of a source gas;

FIG. 40 is a graph illustrating an epi-crown height based on a difference in a method of mounting a SiC wafer; and

FIG. 41 is a graph illustrating an epi thickness based on a difference in a method of mounting a SiC wafer.

### DESCRIPTION OF THE PREFERRED EMBODIMENTS

### Basis of Present Disclosure

As a basic technique related to a susceptor which is a wafer mounting apparatus of the present disclosure, a conventional example and problems thereof will be described. In recent years, there has been an increasing demand for single crystal epitaxial wafers containing SiC as a constituent material as a substrate for high withstand voltage electronic devices and the like.

When a power device is manufactured using a SiC single crystal wafer (hereinafter abbreviated as a “SiC wafer”), it is common to grow a SiC single crystal thin film on the SiC wafer by a thermal chemical vapor deposition method (hereinafter referred to as a “thermal chemical vapor deposition (CVD) method”), block a basal plane dislocation (BPD) on the SiC wafer, and form the device in a layer in which a doping concentration of impurities is controlled. When epitaxial growth is performed by a thermal CVD method, a SiC wafer is placed on a susceptor in an apparatus, and a silicon source gas such as a silane gas or a chlorosilane gas or a carbon source gas such as propane or methane is supplied together with a carrier gas such as hydrogen onto the wafer while the susceptor is rotated to perform epitaxial growth. The silicon source gas and the carbon source gas described above serve as source gases for epitaxial growth.

In order to prevent the SiC wafer from shifting during the epitaxial growth, the susceptor is generally provided with a counterbore (recess) corresponding to the wafer thickness, and the source gas described above is caused to laterally flow to the SiC wafer set therein so as to be substantially horizontal to the front surface of the SiC wafer.

In a SiC wafer of 6 inches or more, warping of the SiC wafer during epitaxial growth increases, and thus a bowl-shaped (recessed) counterbore bottom surface is often applied as a wafer mounting surface. By holding the SiC wafer at a wafer outer peripheral portion, it is possible to prevent contact between a wafer center portion and the counterbore bottom surface during film formation, and prevent a decrease in temperature of the wafer center portion. This effect improves in-plane uniformity of a film thickness and carrier concentration of an epitaxial layer.

The in-plane uniformity of the film thickness and the carrier concentration is an important index of the epitaxial growth layer. For example, film thickness unevenness is likely to occur in the outer peripheral portion of the SiC wafer, and a region of several mm from an outermost peripheral portion of the wafer cannot be used for device production. This unusable region is called edge exclusion or end cut, but if this region can be reduced, the region where semiconductor chips can be formed can be expanded, and the yield of the semiconductor chip can be improved. Therefore, it is preferable that the edge exclusion and end cut are small.

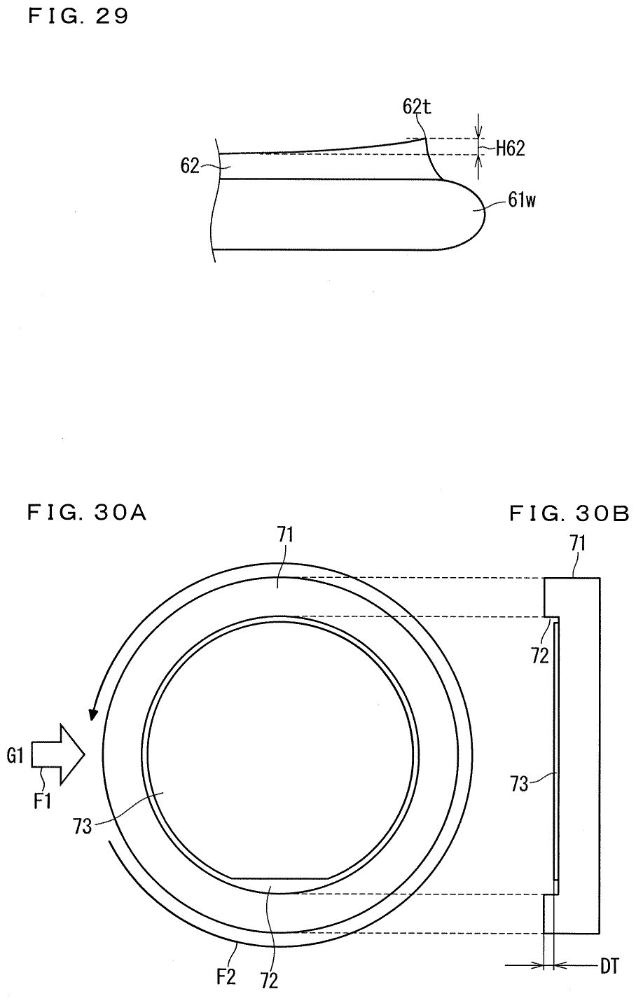

FIG. 29 is an explanatory view schematically illustrating an epi-crown phenomenon. As illustrated in the drawing, an N⁻ epitaxial layer 62 is formed on a front surface of a SiC wafer 61w.

In epitaxial growth in the semiconductor field, as illustrated in FIG. 29, it is known that the film thickness of the N⁻ epitaxial layer 62 increases at the wafer outer peripheral portion, which is a region near an end portion on a front surface of the SiC wafer 61w, and as a result, an epi-crown 62t higher by an epi-crown height H62 than a front surface of the other region of the N epitaxial layer 62 is generated. When the epi-crown 62t is generated, the edge exclusion needs to be increased, so that the elimination of the epi-crown 62t is required.

Several methods have been proposed so far for the resolution of epi-crown. The technique disclosed in Japanese Patent Application Laid-Open No. 7-226349 (1995) is a technique of making the film thickness of the wafer outer peripheral portion of the SiC wafer thinner than the other region in advance along with the growth of the epi-crown, and preventing the film thickness of the outer peripheral portion from becoming thicker than the other region even if the epi-crown occurs.

The technique disclosed in Japanese Patent Application Laid-Open No. 2014-27006 is a technique for removing the formed epi-crown after epitaxial growth. In addition, the technique disclosed in Japanese Patent Application Laid-Open No. 2016-119472 is a technique of increasing a wafer susceptor top distance, which is a step length between the front surface of the SiC wafer and the upper surface of the susceptor, in order to suppress supply of the source gas to the outer peripheral portion of the wafer.

However, in the method of thinning the outer peripheral portion of the wafer in advance as in the technology disclosed in Japanese Patent Application Laid-Open No. 7-226349 (1995), it is necessary to remove the outer peripheral portion in accordance with the film thickness of the epitaxial layer to be formed and the film thickness of the epi-crown to be formed at that time, and the wafer with a thinned outer peripheral portion is a dedicated wafer for forming an epitaxial layer having a specific thickness.

In an actual production site, since the specifications of the epitaxial layer required depending on the type of device to be manufactured are different, it is not desirable to prepare and stock wafers dedicated to specific film forming conditions since the production efficiency is significantly deteriorated.

As in the technique disclosed in Japanese Patent Application Laid-Open No. 2014-27006, in the case of removing the epi-crown after growing the epitaxial layer, since the vicinity of the removed epi-crown is scraped by polishing, there is also a problem that the epitaxial layer is roughened due to damage during polishing. A semiconductor device formed on such a polished surface is likely to be poor in performance, and thus the yield of the semiconductor chip is not necessarily improved. In addition, the methods disclosed in Japanese Patent Application Laid-Open No. 2014-27006 and Japanese Patent Application Laid-Open No. 7-226349 (1995) also have a problem that the number of steps for removing epi-crown increases.

On the other hand, the technique disclosed in Japanese Patent Application Laid-Open No. 2016-119472 is excellent in that there is no wafer processing as compared with Japanese Patent Application Laid-Open No. 2014-27006 and Japanese Patent Application Laid-Open No. 7-226349 (1995), but it has been newly found that there are the following problems as the examination proceeds.

FIGS. 30A and 30B are explanatory views schematically illustrating a conventional susceptor used for film formation. FIG. 30A illustrates a planar configuration of the susceptor, and FIG. 30B illustrates a cross-sectional structure of the susceptor.

As illustrated in FIGS. 30A and 30B, a SiC wafer 73 is accommodated in a circular counterbore 72 of a susceptor 71. A source gas G1 is supplied along a source supply direction F1 above a front surface of the SiC wafer 73. In this manner, the source gas G1 serving as a source gas for epitaxial growth flowing along a flow F2 of the source gas is supplied.

Here, as illustrated in FIG. 30B, the distance between the uppermost surface of the susceptor 71 and the front surface of the SiC wafer 73 is a wafer susceptor top distance DT.

By executing a thermal CVD method of heating the SiC wafer 73 by a heating mechanism (not illustrated) provided on the susceptor 71 in a state where the source gas G1 is supplied, an epitaxial layer can be formed on the front surface of the SiC wafer 73.

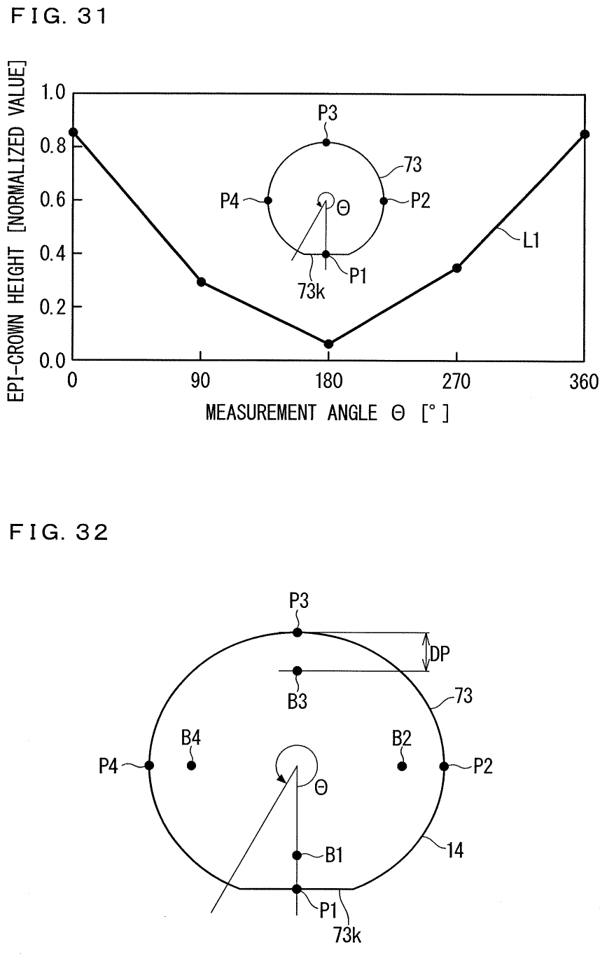

FIG. 31 is a graph illustrating a result of normalizing an epi-crown height (four points in a plane) when an epitaxial layer is grown on a front surface of a 6-inch SiC wafer 73 using the susceptor 71 illustrated in FIGS. 30A and 30B by an average epi thickness of the wafer. FIG. 32 is an explanatory diagram schematically illustrating a relationship between measurement points P1 to P4 and reference points B1 to B4 on the front surface of the SiC wafer 73.

Four in-plane points illustrated in FIG. 31 are measurement points P1 to P4 along an outer periphery of the SiC wafer 73. Note that an epi-crown height indicated by an epi-crown height change L1 in FIG. 31 indicates a difference between an epi thickness of the outermost peripheral portion and an epi thickness of a position at about 5 mm inward from the end of the SiC wafer 73. That is, a difference in epi thickness between a measurement point Pi (any one of i=1 to 4) illustrated in FIG. 32 and a reference point Bi is illustrated. A distance DP illustrated in FIG. 32 indicates a distance of about 5 mm inward from the end of the SiC wafer 73.

As illustrated in FIG. 31, an epi-crown height at the measurement point P1 at which the measurement angle θ is 0° (360°) is the maximum value. As described above, it can be seen that a high epi-crown is formed protruding to the center of an orientation flat portion 73k in an outer peripheral portion of the front surface of the SiC wafer 73. Hereinafter, the orientation flat center portion may be simply referred to as an “OF center portion”, and the orientation flat portion may be simply referred to as an “OF portion”.

An index corresponding to the “step between an upper surface of a susceptor and an upper surface of a silicon wafer” disclosed in Japanese Patent Application Laid-Open No. 2016-119472 is the wafer susceptor top distance DT illustrated in FIGS. 30A and 30B.

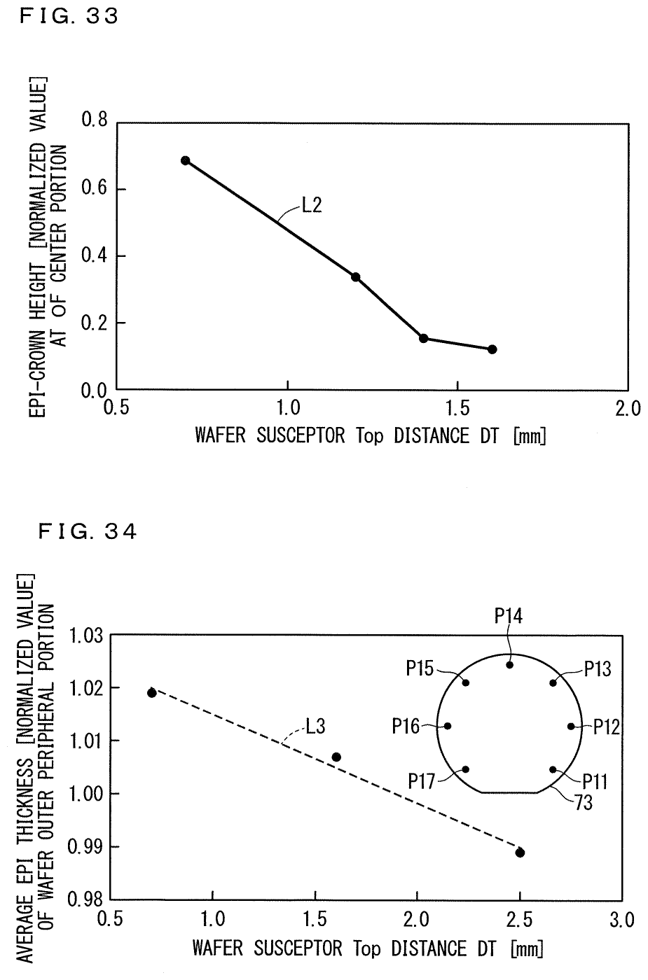

FIG. 33 is a graph illustrating a result of examining the correlation of the height of the epi-crown (normalized by an average epi thickness) at the OF center portion when the wafer susceptor top distance DT is changed. From an epi-crown height change L2 at the OF center portion illustrated in FIG. 33, as the wafer susceptor top distance DT is increased, a result in which the epi-crown at the OF center portion is decreased is obtained, and the technique disclosed in Japanese Patent Application Laid-Open No. 2016-119472 seems to be effective. However, it has been newly found that the wafer susceptor top distance DT is a parameter that not only affects the epi-crown but also affects the epi thickness of the entire wafer outer peripheral portion.

FIG. 34 is a graph illustrating the correlation between the average epi thickness of the wafer outer peripheral portion and the wafer susceptor top distance DT. As indicated by measurement points P11 to P17 in FIG. 34, the average epi thickness is a value obtained by normalizing measurement values at the seven measurement points P11 to P17 excluding the region located at 5 mm from the end portion of the SiC wafer 73 and close to the OF portion with the average epi thickness of the SiC wafer 73.

From an average epi thickness change L3 in the wafer outer peripheral portion illustrated in FIG. 34, it can be seen that the epi thickness in the outer peripheral portion of the SiC wafer 73 decreases as the wafer susceptor top distance DT increases.

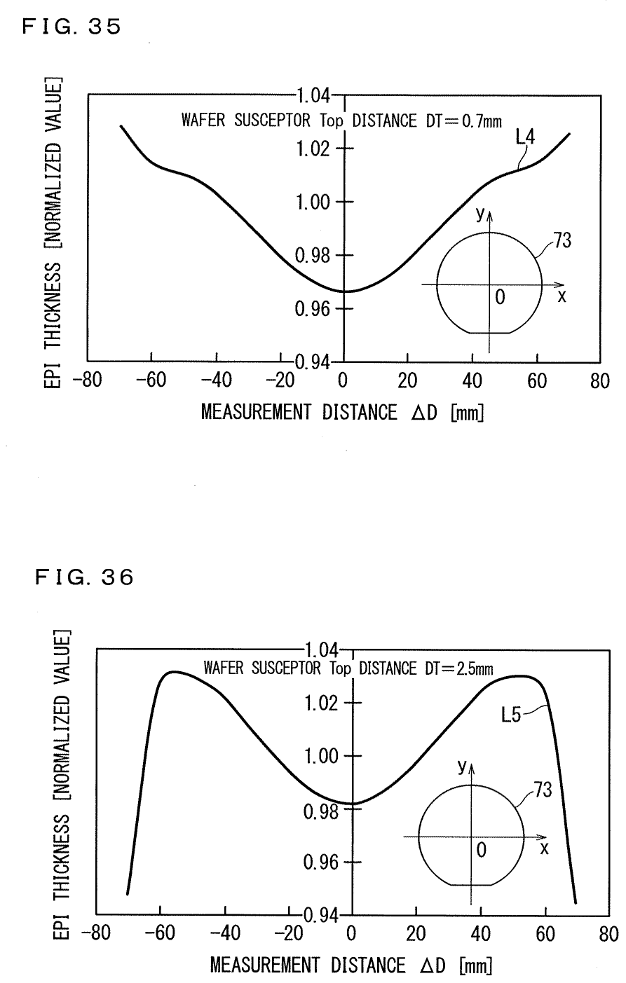

FIG. 35 is a graph illustrating an epi thickness along an X direction when the wafer susceptor top distance DT is 0.7 mm. FIG. 36 is a graph illustrating an epi thickness along the X direction when the wafer susceptor top distance DT is 2.5 mm. Note that the epi thickness is indicated by a value normalized by the average epi thickness of the SiC wafer 73.

In each of FIGS. 35 and 36, the origin “0” intersecting the X axis and the Y axis is a position where a predetermined distance ΔD is “0”, the predetermined distance ΔD on a +X direction side is a positive distance [mm], and the predetermined distance ΔD on a −X direction side is a negative distance [mm].

From an epi thickness change LA illustrated in FIG. 35 and an epi thickness change L5 illustrated in FIG. 36, it can be seen well that the epi thickness of the outer peripheral portion of the SiC wafer 73 greatly changes as the wafer susceptor top distance DT increases. Furthermore, as can be seen from an epi thickness change L5 illustrated in FIG. 36, the epi thickness sharply decreases in the vicinity of the end portion of the SiC wafer 73 where the predetermined distance ΔD is about +70 mm.

Although the epi-crown generated in the outermost peripheral portion of the SiC wafer 73 can be suppressed, if the epi thickness of the wafer outer peripheral portion is significantly reduced, the technique disclosed in Japanese Patent Application Laid-Open No. 2016-119472 cannot be put into a semiconductor chip manufacturing process and reduces the wafer yield in the epitaxial growth process, which is not desirable.

A wafer mounting apparatus (susceptor) of the present disclosure is intended to reduce an ineffective region of a wafer by suppressing epi-crown without extremely reducing the epi thickness of the wafer outer peripheral portion.

The inventors of the wafer mounting apparatus of the present disclosure have conducted various studies to investigate a factor of forming a high epi-crown in the OF portion and a region in the vicinity thereof, and have found one factor. It is the distance between the wafer and the counterbore inner wall.

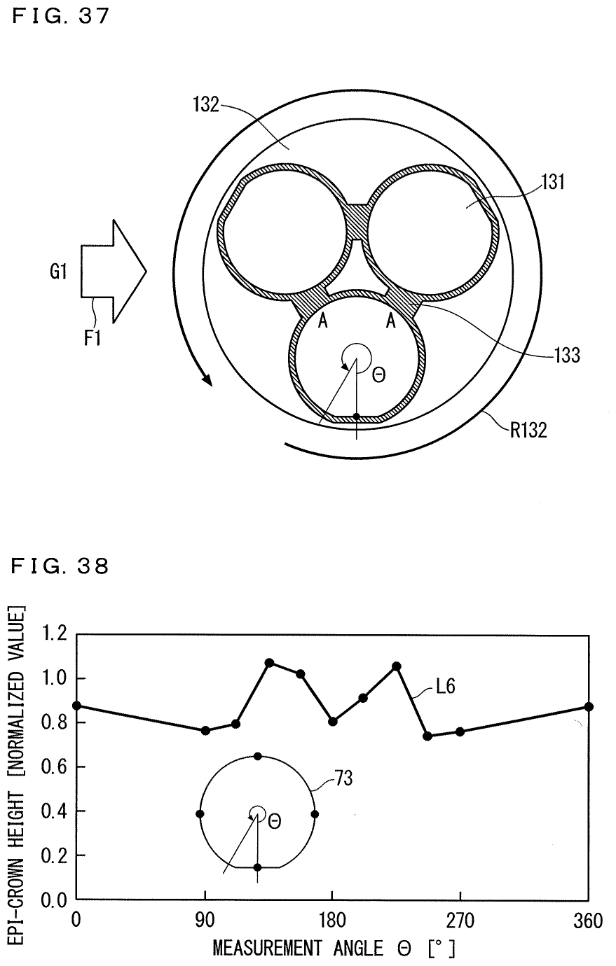

FIG. 37 is an explanatory view schematically illustrating a planar configuration of a conventional susceptor. As illustrated in the drawing, a susceptor 132 has three semiconductor wafers 131 such as SiC wafers mounted in a counterbore 133. The source gas G1 is supplied along the source supply direction F1 above the three semiconductor wafers 131 while rotating the susceptor 132 along a susceptor rotation direction R132.

FIG. 38 is a graph illustrating an example of an epi-crown height when an epitaxial layer is formed on a front surface of the semiconductor wafer 131 using the susceptor 132 illustrated in FIG. 37. Note that the epi-crown height indicated by an epi-crown height change L6 is normalized by the average epi thickness.

As illustrated in FIG. 38, the epi-crown has two peaks on the opposite side of the OF portion, and the portion indicating the peak corresponds to the portion indicated by “A” in FIG. 37. When considered together with the result illustrated in FIG. 31, it can be seen that the distance between the wafer outer periphery and the counterbore inner wall affects the epi-crown.

From these results, it can be said that it is important to use a counterbore whose counterbore inner wall and the wafer end are not extremely separated from each other, that is, a counterbore having a shape conforming to the wafer shape in order to suppress the epi-crown.

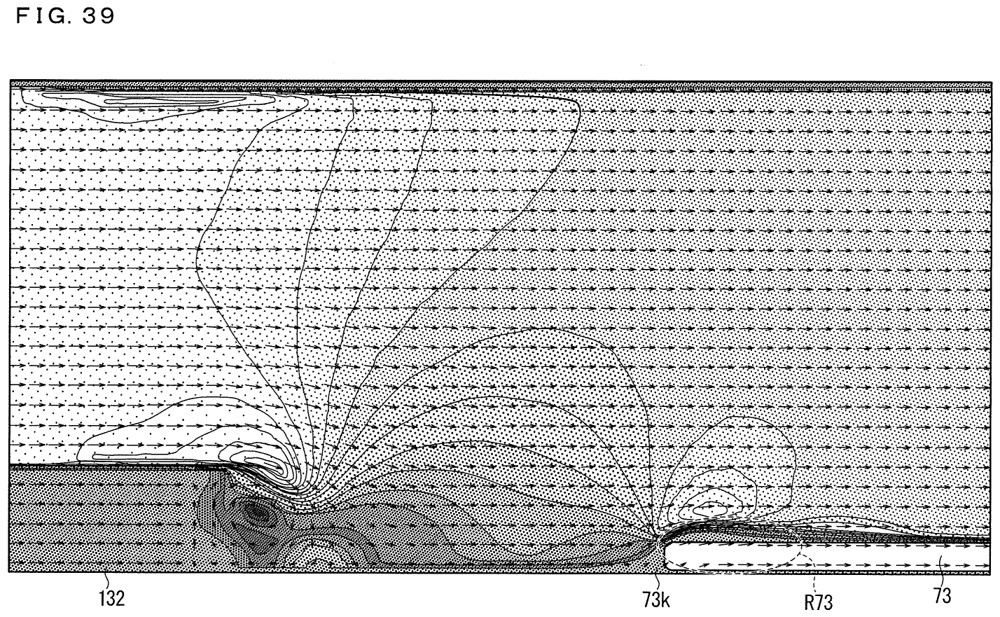

FIG. 39 is an explanatory diagram illustrating a fluid simulation result regarding the fluid velocity of the source gas G1. Dot concentration in the drawing has a negative correlation with a flow rate of the source gas G1, and a region having a higher dot concentration indicates that the flow rate of the source gas G1 is slower.

As illustrated in FIG. 39, the source gas G1 having passed over the susceptor 132 passes through the wafer mounting surface, collides with the end portion of the SiC wafer 73 such as the orientation flat portion 73k, and is then supplied to the front surface of the SiC wafer 73. That is, the end peripheral region R73 of the SiC wafer 73 is a region where the flow rate of the source gas G1 is the slowest.

Therefore, the end peripheral region R73 where the flow rate of the source gas G1 for epitaxial growth is the slowest is a region where the degree of epitaxial growth is the highest, and as a result, it is conceivable that epi-crown is formed in the end peripheral region R73.

Therefore, when the counterbore inner wall and the end portion of the SiC wafer 73 are close to each other, the source gas G1 is supplied to the front surface of the semiconductor wafer 131 without passing through the wafer mounting surface of the counterbore 133, and as a result, it is possible to avoid formation of a region where the flow velocity of the source gas G1 decreases, such as the end peripheral region R73 in FIG. 39, and thus it is conceivable to be effective for suppressing epi-crown.

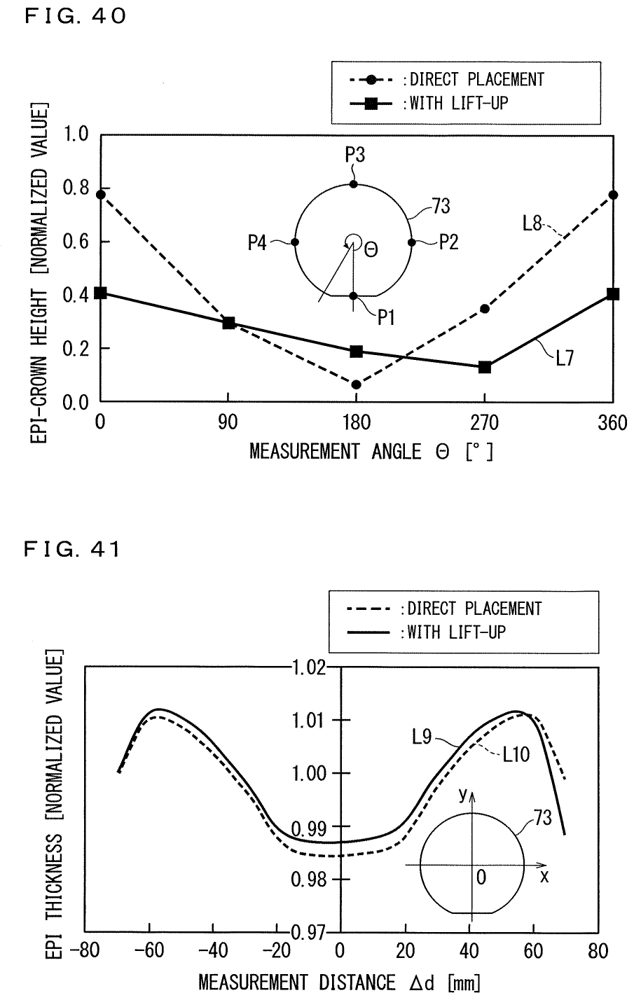

Next, a method of holding a semiconductor wafer was studied. FIG. 40 is a graph illustrating an epi-crown height based on a difference in a method of mounting a SiC wafer.

An epi-crown height change L8 indicates a normalized value of the epi thickness when a 6-inch SiC wafer is used as the SiC wafer 73 and the SiC wafer 73 is directly placed on the mounting surface. An epi-crown height change L7 indicates a normalized value of the epi thickness when the SiC wafer 73 is lifted up at several points and the wafer back surface and the susceptor are separated (hereinafter, this may be described as “lift-up”).

Note that the counterbore has a shape conforming to the shape of the SiC wafer 73, and the wafer susceptor top distance DT is equal between the epi-crown height change L7 and a epi-crown height change L8. As indicated by the epi-crown height change L8, in the case of direct placement even in the counterbore shape conforming to the shape of the SiC wafer 73, a high epi-crown is still formed in the OF portion. On the other hand, as indicated by the epi-crown height change L7, when the SiC wafer 73 is lifted up, the epi-crown of the OF portion decreases.

This is conceivably because a space is formed on the back surface side of the SiC wafer 73 by lift-up, and thus a part of the source gas G1 escapes to the back surface of the SiC wafer 73.

FIG. 41 is a graph illustrating an epi thickness along the X direction based on a difference in a method of mounting a SiC wafer. An epi thickness change L9 indicates a normalized value of the epi thickness when the SiC wafer 73 is lifted up, and an epi thickness change L10 indicates a normalized value of the epi thickness when the SiC wafer 73 is directly placed.

In FIG. 41, the origin “0” intersecting the X axis and the Y axis is a position where a predetermined distance ΔD is “0”, the predetermined distance ΔD on a +X direction side is a positive distance [mm], and the predetermined distance ΔD on a −X direction side is a negative distance [mm].

As indicated by the epi thickness changes L9 and L10 in FIG. 41, when both the wafer susceptor top distances DT are equal to each other, no significant change occurs in the in-plane distribution shape of the epi thickness.

From the above experimental results, the inventors have provided the wafer mounting apparatus of the present disclosure. In the wafer mounting apparatus of the present disclosure, a susceptor having an opening having a wall portion corresponding to the shape of the semiconductor wafer is provided so that the distance between a counterbore inner wall and a wafer end is not extremely separated, and the epitaxial growth process can be performed in a state where the semiconductor wafer is lifted up.

By lifting up and mounting the semiconductor wafer, a space is formed on the back surface of the semiconductor wafer, and a part of the source gas is released into the space, so that epi-crown can be reduced.

A point of epi-crown reduction is to release a part of the source gas G1 supplied to the surface of the semiconductor wafer to the back surface of the semiconductor wafer. Therefore, the wafer mounting apparatus of the present disclosure is characterized in that an annular groove having an annular shape is provided on the wafer mounting surface below the outermost peripheral portion of the semiconductor wafer to ensure a flow path of the source gas G1, and a flow path of the source gas G1 formed around the OF portion where the high epi-crown is formed is deeper than the other region.

The wafer mounting apparatus of the present disclosure obtained based on the above technical consideration is the wafer mounting apparatus described in the following first to fourth preferred embodiments.

### Wafer Mounting Apparatus of Present Disclosure

### (Introduction)

Hereinafter, a susceptor which is a wafer mounting apparatus of the present disclosure and a semiconductor manufacturing apparatus for a SiC wafer (SiC epitaxial wafer) will be described. Note that, in the drawings used in the following description, in order to facilitate understanding of characteristics of the wafer mounting apparatus of the present disclosure, characteristic portions may be illustrated in an enlarged manner for convenience, and the dimensional ratios and the like of the respective components may be different from the actual ones. In addition, materials, dimensions, and the like exemplified in the following description are merely examples, and the present disclosure is not limited thereto, and can be appropriately changed and implemented without changing the gist thereof.

### (Semiconductor Manufacturing Apparatus)

FIG. 25 is an explanatory view schematically illustrating a cross-sectional structure of a semiconductor manufacturing apparatus 50 including a susceptor 11 and the like according to a first preferred embodiment of the present disclosure. The semiconductor manufacturing apparatus 50 is also called an “SiC epitaxial wafer manufacturing apparatus” and is an apparatus for forming an epitaxial layer on a front surface of a SiC wafer. Although the semiconductor manufacturing apparatus 50 is not limited to the configuration illustrated in FIG. 25, in order to facilitate understanding, a preferred embodiment described below will be described based on the semiconductor manufacturing apparatus 50 illustrated in FIG. 25.

The semiconductor manufacturing apparatus 50 illustrated in FIG. 25 is an apparatus called a planetary susceptor type, and includes a top plate 185 in an upper portion in a chamber 181, a planetary susceptor 182 and an induction heating coil 188 in a lower portion, and an injector 186 so as to vertically penetrate the chamber 181 from a center portion of the top plate 185.

In an upper portion of the planetary susceptor 182, a plurality of satellite disks 183 is arranged in a plurality of accommodation regions 189 around a center part 187, a SiC wafer 184 is set in the satellite disks 183, the source gas G1 radially flows from the injector 186, and epitaxial growth is performed on a front surface of the SiC wafer 184. Epitaxial growth on a front surface of the satellite disk 183 is performed in a temperature range of about 1400° C. to 1700° C. by a heating treatment using the induction heating coil 188.

Then, when the inside of the semiconductor manufacturing apparatus 50 reaches a desired temperature, a dopant gas is placed on the carrier gas in addition to a silicon-based gas (silicon source gas) and a hydrocarbon gas, the source gas G1 is made to flow from the side so as to be substantially horizontal to the SiC wafer 184, and an epitaxial growth process is performed. Silane (SiH₄), dichlorosilane (SiCl₂H₂), trichlorosilane (SiCl₃), silicon tetrachloride (SiCl₄), and the like is conceivable as the silicon source gas, and propane (C₃H₈), ethane (C₂H₆), and the like is conceivable as the hydrocarbon gas as the carbon source gas.

For the purpose of improving the growth rate in the epitaxial growth process, HCl may be added or the source gas G1 containing C1 such as SiH₂Cl₂ may be used. Since the source gas G1 for epitaxial growth introduced from the injector 186 reaches the outside of the chamber 181 while being consumed for epitaxial growth, the growth rate and the carrier concentration are different between upstream and downstream. Thus, while the planetary susceptor 182 is mechanically rotated along a susceptor rotation direction R182 in a state where the source gas G1 is supplied, the satellite disk 183 is rotated along a disk rotation direction R183 by the disk rotation gas G2 blown onto a lower surface of the satellite disk 183.

Such an epitaxial growth process is executed to improve the uniformity of the carrier concentration and the film thickness in the epitaxial layer. When the epitaxial layer has a desired film thickness, the supply of the source gas G1 is stopped and the temperature is lowered. After falling to a predetermined temperature, the SiC wafer 184 is removed and a series of epitaxial growth processes ends.

Next, the susceptor of the present disclosure will be described. A ring is set in the satellite disk 183 described above to prevent displacement of the SiC wafer 184 during film formation. A generic name of a wafer holder heated by induction heating by the induction heating coil 188, a heater, or the like is referred to as a “susceptor”.

Therefore, in the preferred embodiment described below, there is no problem if a combination of a satellite disk and a ring is referred to as a susceptor, and hereinafter, for the sake of simplicity, a structure in which this combination is a main component is described as a “susceptor” of the present disclosure.

An advantage of the susceptor including two of the satellite disk and the ring is that the degree of freedom of usable materials and coating materials is increased, for example, by combining a SiC ring with a TaC-coated satellite disk. For example, when the epitaxial growth process is performed in an overlapping manner, it is conceivable that a deposit adhering to the inner wall of the ring interferes with the semiconductor wafer, and the semiconductor wafer cannot be set. However, when a SiC bulk ring is applied, SiC is strong, so that the deposit can be mechanically removed to enable reuse, and the part cost can be suppressed.

In addition, when the center portion of the semiconductor wafer is compared with an outer peripheral portion that is a peripheral region of the center portion, the temperature of the outer peripheral portion is likely to decrease. However, when a ring covered with some coating material is applied to a carbon base material and the resistivity of the base material of the ring is made higher than that of the base material of the satellite disk, the heat generation of the ring becomes larger than that of the satellite disk at the time of induction heating, and it is also possible to suppress the temperature decrease of the outer peripheral portion of the semiconductor wafer. In order to obtain the degree of freedom, the present disclosure employs the susceptor having the combination of a satellite disk and a ring as a main component.

### First Preferred Embodiment

### (Basic Configuration)

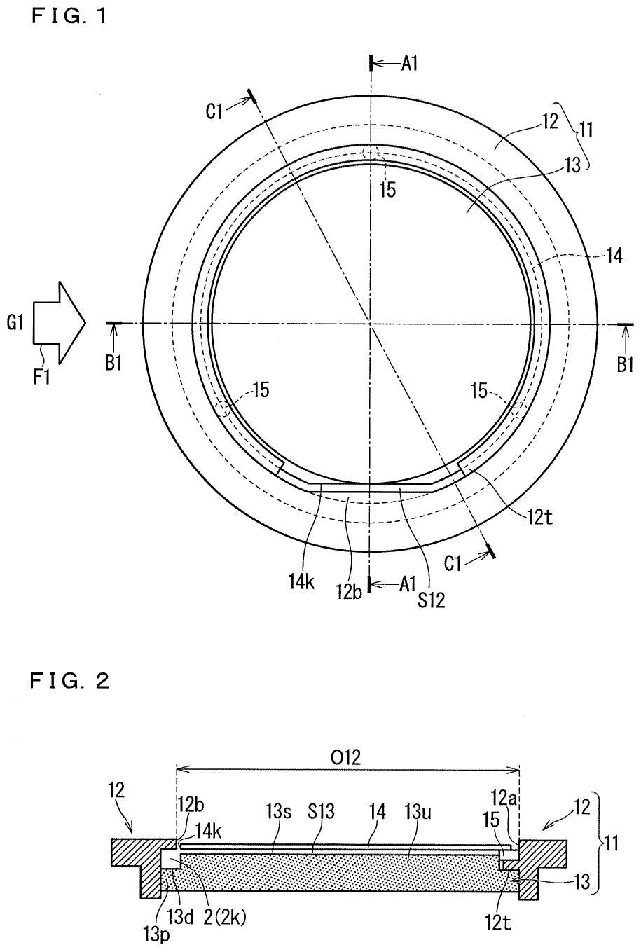

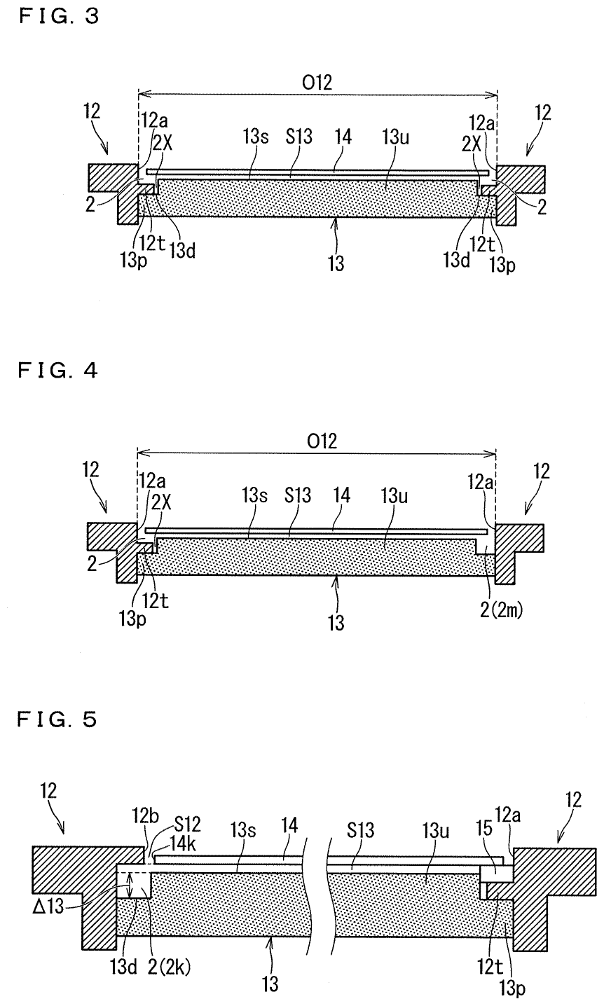

FIG. 1 is an explanatory view schematically illustrating a planar configuration of a susceptor 11 as a basic configuration of the first preferred embodiment of the present disclosure. FIG. 2 is an explanatory view schematically illustrating a configuration of an A1-A1 cross section of FIG. 1, FIG. 3 is an explanatory view schematically illustrating a configuration of a B1-B1 cross section of FIG. 1, and FIG. 4 is an explanatory view schematically illustrating a configuration of a C1-C1 cross section of FIG. 1. FIG. 5 is an explanatory view illustrating an enlarged cross-sectional configuration of FIG. 2. Note that, in FIG. 1, planar structures of a ring 12 and a satellite disk 13, which are main components of the susceptor 11, are schematically illustrated in an easily recognizable manner.

A mounting target of the susceptor 11, which is a basic configuration of the wafer mounting apparatus of the first preferred embodiment, is a SiC wafer 14 having an orientation flat portion 14k. That is, the susceptor 11 of the first preferred embodiment is a wafer mounting apparatus on which the SiC wafer 14 having the orientation flat portion 14k is mounted. The SiC wafer 14 is a semiconductor wafer having the orientation flat portion 14k as a cutout portion.

As illustrated in FIGS. 1 to 5, the susceptor 11 includes, as main components, a combination of the satellite disk 13, which is a disk having a circular shape in plan view and a protruding cross section, and the ring 12. The ring 12 is provided with a wall portion 12a and a wall portion 12b on an upper side, and has an opening O12 with the wall portion 12a and the wall portion 12b as outer peripheries. The opening O12 has a shape approximate to the wafer shape of the SiC wafer 14, and the opening O12 has a planar shape including the SiC wafer 14 in plan view and slightly larger than the SiC wafer 14.

As illustrated in FIGS. 2 to 5, the cross-sectional structure of a portion having a terrace portion 12t of the ring 12 has a deformed T-shaped cross-sectional structure having a region protruding in a direction approaching and a direction away from the opening O12.

The satellite disk 13, which is a disk of the basic configuration, includes an upper layer portion 13u, which is a protrusion, and includes a peripheral portion 13p around the upper layer portion 13u. A peripheral portion front surface 13d of the peripheral portion 13p has a formation height lower than a front surface 13s of the upper layer portion 13u, and as illustrated in FIG. 5, a step 413 exists in a height direction from the peripheral portion surface 13d to the front surface 13s.

The wall portion 12b of the ring 12 functions as a cutout-side protruding wall portion protruding toward a side of the opening O12 corresponding to the orientation flat portion 14k which is a cutout portion of the SiC wafer 14. As illustrated in FIG. 1, the wall portion 12b is provided in parallel with the orientation flat portion 14k in plan view, and a gap space S12 in which a length in a lateral direction is a constant interval exists between the wall portion 12b and the orientation flat portion 14k.

As illustrated in FIGS. 2 and 5, an upper surface of the wall portion 12b serving as the cutout-side protruding wall portion is provided to be a part of an upper surface of the entire ring 12. That is, the formation height of the upper surface of the wall portion 12b coincides with the formation height of the upper surface of the ring 12. Furthermore, the lower surface of the wall portion 12b does not have a contact relationship with the peripheral portion front surface 13d of the peripheral portion 13p of the satellite disk 13.

The ring 12 further includes a terrace portion 12t protruding toward the side of the opening O12 in an intermediate region in the height direction, and as illustrated in FIG. 1, the terrace portion 12t does not overlap the wall portion 12b, which is the cutout-side protruding wall portion, in plan view.

The ring 12 is mounted on the satellite disk 13 in such a manner that the terrace portion 12t of the ring 12 is supported by the peripheral portion front surface 13d of the peripheral portion 13p of the satellite disk 13. That is, the satellite disk 13 supports the ring 12 by supporting the terrace portion 12t from the back surface by the peripheral portion front surface 13d.

The three lift-up pins 15, which are a plurality of lift-up members each having the same formation height, are discretely mounted on the front surface of the terrace portion 12t in the ring 12.

The three lift-up pins 15 hold the SiC wafer 14 by supporting the SiC wafer 14 from the back surface. In the first preferred embodiment, the front surface of the terrace portion 12t is a lift-up region for the three lift-up pins 15.

Since the upper surface of the wall portion 12b is a part of the upper surface of the ring 12, the formation height of the upper surface of the wall portion 12b coincides with the formation height of the upper surface of the entire ring 12. The upper surface of the wall portion 12b is set to be equal to or higher than the formation heights of the upper surfaces of three lift-up pins 15.

As described above, the susceptor 11, which is the basic configuration of the first preferred embodiment, includes the ring 12, the satellite disk 13, and the three lift-up pins 15 as main components.

In the susceptor 11 of the first preferred embodiment having such a configuration, the SiC wafer 14 can be held by mounting the SiC wafer 14 on the three lift-up pins 15 so that the SiC wafer 14 fits within the opening O12 in plan view without being in contact with the ring 12. This state is the semiconductor wafer mounting state related to the SiC wafer 14.

In the semiconductor wafer state related to the SiC wafer 14, the wall portion 12b, which is the cutout-side protruding wall portion, and the orientation flat portion 14k are in a positional relationship of facing each other via the gap space S12 having a constant interval.

Since the SiC wafer 14 mounted in this manner is disposed in the opening O12 in plan view without having a contact relationship with the ring 12, an annular gap is always formed between an outer peripheral surface of the SiC wafer 14 and the opening O12. The annular gap includes the gap space S12 described above.

In addition, since the opening O12 is formed to approximate the shape of the SiC wafer 14, the annular gap is provided at a constant interval without bias. This annular gap also functions as a gas escape flow path to be described later.

When the SiC wafer 14 is mounted on the three lift-up pins 15, the disk upper space S13 is formed between the front surface 13s of the upper layer portion 13u of the satellite disk 13 and the back surface of the SiC wafer 14 except for a formation region of the three lift-up pins 15.

Furthermore, a groove 2, which is an annular groove having an annular shape along the outer periphery of the opening O12 in plan view, is formed between the upper layer portion 13u of the satellite disk 13 and the ring 12 on the back surface side of the SiC wafer 14.

The annular groove 2 has one side surface as a side surface of the upper layer portion 13u and the other side surface as the wall portion 12a. Then, the groove 2 formed in the formation region of the terrace portion 12t is a space above the terrace portion 12t with the terrace portion 12t as a bottom surface.

On the other hand, as illustrated in FIGS. 2 and 5, in the region where the terrace portion 12t is not formed, the groove 2 immediately below the wall portion 12b is a groove 2k. Further, as illustrated in FIG. 4, the groove 2 located immediately below both end peripheral regions of the wall portion 12b is a groove 2m. Both the groove 2k and the groove 2m are spaces above the peripheral portion front surface 13d with the peripheral portion front surface 13d of the peripheral portion 13p as a bottom surface.

Hereinafter, in the present specification, the annular groove 2 will be described as including the groove 2k (groove 2n) and the groove 2m (groove 2m2) in a broad sense, and indicating only the groove 2 with the terrace portion 12t as a bottom surface in a narrow sense.

The annular gap formed between the outer peripheral surface of the SiC wafer 14 and the opening O12 and the groove 2 which is an annular groove described above serve as a gas escape flow path for releasing the source gas G1 supplied to the front surface of the SiC wafer 14 to the disk upper space S13.

The terrace portion 12t of the ring 12 is provided so as not to have a contact relationship with the side surface of the upper layer portion 13u of the satellite disk 13. Therefore, an auxiliary groove 2X communicating with the groove 2 in the depth direction can be provided between a front end of the terrace portion 12t and the side surface of the upper layer portion 13u. The auxiliary groove 2X makes it possible to increase the formation depth of a part of the groove 2 and to increase the volume of the gas escape flow path.

In FIGS. 1, 2, and 5, the lift-up pins 15 are illustrated in a cylindrical shape, but may have any shape, and while at least three lift-up pins are necessary for holding the SiC wafer 14, the number of lift-up pins is not limited as long as three or more lift-up pins are provided.

A place where the lift-up pin 15 and the SiC wafer 14 are in contact with each other has a temperature different from other regions and may affect film quality, and thus, for example, it is desirable to hold the SiC wafer 14 in an edge exclusion region. Therefore, it is preferable that the position of the lift-up pin 15 is provided on the outside as much as possible so as to be in contact with the wall portion 12a of the ring 12.

There is no problem even if the lift-up pin 15 is provided so as not to come into contact with the wall portion 12a, but there is a possibility that it becomes difficult to manufacture the ring 12 by machining or the like with an NC machining machine.

As illustrated in FIGS. 2 to 5, the terrace portion 12t is formed to have a thickness in the height direction smaller than the step difference Δ13 between the upper layer portion 13u and the peripheral portion 13p in the satellite disk 13. Therefore, when the satellite disk 13 and the ring 12 are combined with each other, the annular groove 2 is always formed also in the formation region of the terrace portion 12t.

As described above, the formation position of the lower surface of the wall portion 12b is located between the front surface of the ring 12 and the back surface of the SiC wafer 14, but is desirably located between the front surface and the back surface of the SiC wafer 14.

In FIG. 5, the lower surface of the wall portion 12b corresponding to the orientation flat portion 14k of the SiC wafer 14 is aligned in height with the upper surfaces of the three lift-up pins 15 (the back surface of the SiC wafer 14). In addition, the ring 12 is configured such that the terrace portion 12t is not formed at a location corresponding to the orientation flat portion 14k. Therefore, the groove 2k serving as a gas escape flow path for the source gas G1 to escape into the disk upper space S13 on the back surface side of the SiC wafer 14 can be formed deeper than the groove 2 with the terrace portion 12t as a bottom surface.

Similarly, as illustrated in FIG. 4, since the terrace portion 12t is not formed in the end peripheral region of the orientation flat portion 14k, the groove 2m serving as the gas escape flow path can be made deeper than the groove 2 with the terrace portion 12t as a bottom surface.

When the susceptor 11 of the first preferred embodiment having such a configuration is applied to the semiconductor manufacturing apparatus 50 illustrated in FIG. 25, the satellite disk 183 is replaced with the susceptor 11 including the ring 12, the satellite disk 13, and the three lift-up pins 15, and the SiC wafer 184 is replaced with the SiC wafer 14.

When the susceptor 11 of the first preferred embodiment illustrated in FIGS. 1 to 5 is applied to the semiconductor manufacturing apparatus 50 illustrated in FIG. 25, the source gas G1 is supplied from the outside of the rotating susceptor 132 in the planetary susceptor type CVD apparatus. When the orientation flat portion 14k of the SiC wafer 14 approaches the injector 186 and the source gas G1 is supplied from the orientation flat portion 14k side, a part of the source gas G1 flows into the disk upper space S13 through the gap space S12 and the groove 2k between the SiC wafer 14 and the wall portion 12b.

As described above, since the groove 2k is formed relatively deep, the source gas G1 flowing from the gap space S12 between the SiC wafer 14 and the wall portion 12b can be smoothly released to the disk upper space S13 on the back surface side of the SiC wafer 14 via the groove 2k serving as the gas escape flow path.

On the other hand, when the lower surface of the wall portion 12b is lower than the back surface of the SiC wafer 14, the wall portion 12b protrudes to the groove 2k, and there is a concern that the function of the groove 2k as a gas escape flow path is hindered. Therefore, the position of the lower surface of the wall portion 12b is set to be equal to or higher than the height of the front surfaces of the three lift-up pins 15 (the back surface of the SiC wafer 14).

In the susceptor 11, which is the basic configuration of the first preferred embodiment, the terrace portion 12t is supported from below on the front surface of the peripheral portion 13p of the satellite disk 13 to hold the ring 12, and the formation of the terrace portion 12t in the orientation flat portion 14k and the region in the vicinity thereof is omitted.

However, if there is no problem in terms of strength, a plurality of partial terrace portions may be discretely provided instead of the terrace portion 12t continuously formed in a region other than the orientation flat portion 14k and the neighboring region thereof. Note that, here, “there is no problem in terms of strength” means that the weight of the ring 12 can be supported by the terrace portion 12t, and no problem occurs in the terrace portion 12t.

In the susceptor 11, which is the basic configuration of the wafer mounting apparatus according to the first preferred embodiment of the present disclosure, the SiC wafer 14, which is a semiconductor wafer, is mounted on the three lift-up pins 15, which are a plurality of lift-up members, to achieve the semiconductor wafer mounting state related to the SiC wafer 14. Therefore, the disk upper space S13 can be provided between the back surface of the SiC wafer 14 and the front surface 13s of the satellite disk 13.

Further, in the susceptor 11 of the first preferred embodiment, the groove 2 which is an annular groove is formed between the upper layer portion 13u of the satellite disk 13 and the ring 12 on the back surface side of the SiC wafer 14 during the semiconductor wafer mounting state.

Therefore, when the source gas G1 is supplied above the front surface of the SiC wafer 14 in the semiconductor wafer mounting state, a part of the source gas G1 can be intentionally released to the disk upper space S13 on the back surface side of the SiC wafer 14 through the annular gap and the groove 2 along the outer periphery of the SiC wafer 14.

As a result, when the susceptor 11 of the first preferred embodiment executes the epitaxial growth process to form an epitaxial growth layer on the front surface of the SiC wafer 14 in the semiconductor wafer mounting state, the susceptor can suppress the occurrence of an epi-crown phenomenon in which the epi thickness of the epitaxial growth layer locally increases. This epi-crown phenomenon occurs mainly on the outer peripheral portion on the front surface of the SiC wafer 14.

As a result, the susceptor 11 of the first preferred embodiment has an effect of being able to form an epitaxial layer having an epi thickness with excellent in-plane uniformity on the front surface of the SiC wafer 14 in the semiconductor wafer mounting state. Note that an epi thickness and a carrier concentration (impurity concentration) are included as indices of in-plane uniformity.

Furthermore, since the height of the uppermost surface of the ring 12 can be arbitrarily set, the wafer susceptor top distance DT, which is the difference in height between the front surface of the SiC wafer 14 mounted on the three lift-up pins 15 and the uppermost surface of the ring 12, can be set to an optimum length that does not cause an extreme decrease in the epi thickness at the outer peripheral portion of the front surface of the SiC wafer 14.

In the susceptor 11 of the first preferred embodiment, since the ring 12 is mounted on the satellite disk 13 in a mode in which the terrace portion 12t is supported on the peripheral portion front surface 13d of the peripheral portion 13p of the satellite disk 13, a combination structure of the satellite disk 13 and the ring 12 can be achieved without affecting the SiC wafer 14 as a mounting target.

Furthermore, by forming the thickness of the terrace portion 12t in the height direction to be thinner than the step Δ13 between the upper layer portion 13u and the peripheral portion 13p of the satellite disk 13, the groove 2 with the terrace portion 12t as a bottom surface can be formed in the formation region of the terrace portion 12t.

The susceptor 11 of the first preferred embodiment can support the SiC wafer 14 by the three lift-up pins 15, which are a plurality of lift-up members mounted on the terrace portion 12t of the ring 12, with the lift-up region as the surface region of the terrace portion 12t.

In the susceptor 11 of the first preferred embodiment, since the terrace portion 12t does not have a contact relationship with the side surface of the upper layer portion 13u, the auxiliary groove 2X communicating with the groove 2 in the depth direction can be formed between the side surface of the upper layer portion 13u and the protruding distal end portion of the terrace portion 12t.

As a result, since the susceptor 11 of the first preferred embodiment can increase the volume of the groove 2 by the amount of the auxiliary groove 2X, it is possible to improve the function as a gas escape flow path by the groove 2 to release a part of the source gas G1 to the disk upper space S13 on the back surface side of the SiC wafer 14, and to effectively suppress the epi-crown phenomenon.

Since the opening O12 of the ring 12 is shaped to include the SiC wafer 14 and has a larger formation area than the SiC wafer 14, the SiC wafer 14 can be reliably mounted on the three lift-up pins 15 without being brought into contact with the ring 12 including the wall portion 12b serving as the cutout-side protruding wall portion.

Furthermore, by making the opening O12 have an approximate shape conforming to the shape of the SiC wafer 14, the susceptor 11 of the first preferred embodiment can effectively suppress the occurrence of epi-crown.

In addition, since the wall portion 12b, which is the cutout-side protruding wall portion, does not have a contact relationship with the peripheral portion front surface 13d of the peripheral portion 13p of the satellite disk 13, the function as the gas escape flow path of the groove 2k formed below the wall portion 12b is not deteriorated.

In the susceptor 11 of the first preferred embodiment, since the formation height of the lower surface of the wall portion 12b, which is the cutout-side protruding wall portion, is set to be equal to or higher than the formation heights of the upper surfaces of the three lift-up pins 15, the function of the groove 2k formed below the wall portion 12b as the gas escape flow path is not deteriorated.

In addition, in the susceptor 11 of the first preferred embodiment, the upper surface of the wall portion 12b, which is the cutout-side protruding wall portion, is provided to be a part of the upper surface of the ring 12. That is, the formation height of the upper surface of the wall portion 12b coincides with the formation height of the upper surface of the ring 12. Therefore, the groove 2k as the gas escape flow path can be formed below the wall portion 12b having a sufficient thickness.

Since the wall portion 12b, which is the cutout-side protruding wall portion, is disposed to face the orientation flat portion 14k via the gap space S12 having a constant interval during the semiconductor wafer mounting state, the amount of the source gas G1 flowing through the groove 2k via the gap space S12 can be limited so as not to exceed an allowable upper limit amount. This is because if the source gas G1 exceeding the allowable upper limit amount flows into the groove 2k through the gap space S12, the source gas G1 supplied to the front surface of the SiC wafer 14 may fall below an appropriate amount.

Therefore, the susceptor 11 of the first preferred embodiment can supply an appropriate amount of the source gas G1 to the front surface of the SiC wafer 14 having the orientation flat portion 14k.

### First Modification

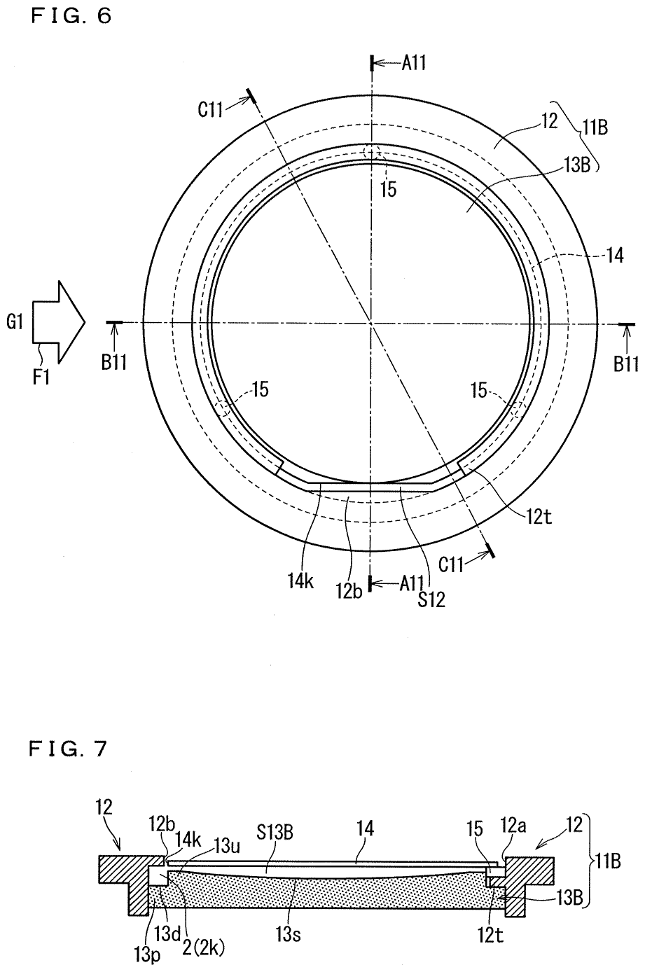

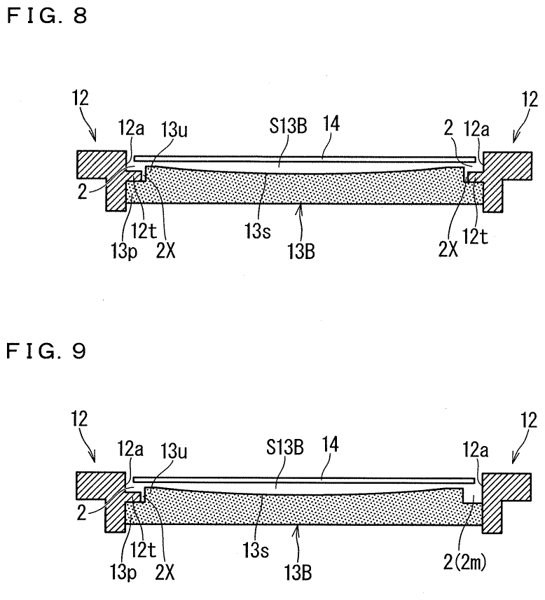

FIG. 6 is an explanatory view schematically illustrating a planar configuration of a susceptor 11B according to a first modification of the first preferred embodiment of the present disclosure. FIG. 7 is an explanatory view schematically illustrating a configuration of a cross section taken along line A11-A11 in FIG. 6, FIG. 8 is an explanatory view schematically illustrating a configuration of a cross section taken along line B11-B11 in FIG. 6, and FIG. 9 is an explanatory view schematically illustrating a configuration of a cross section taken along line C11-C11 in FIG. 6. Note that, in FIG. 6, the planar structures of the ring 12 and a satellite disk 13B, which are main components of the susceptor 11B, are schematically illustrated in an easily recognizable manner.

Similarly to the basic configuration, a mounting target of the susceptor 11B according to the first modification of the wafer mounting apparatus of the first preferred embodiment is the SiC wafer 14 having the orientation flat portion 14k.

Hereinafter, components similar to those of the susceptor 11 having the basic configuration illustrated in FIGS. 1 to 5 will be denoted by the same reference numerals, description thereof will be omitted as appropriate, and features of the susceptor 11B as the first modification will be mainly described.

As illustrated in FIGS. 6 to 9, the susceptor 11B includes, as main components, a combination of a satellite disk 13B, which is a disk having a circular shape in plan view and a protruding cross section, and a ring 12 having a deformed T-shaped cross-sectional structure having a terrace portion 12t.

The satellite disk 13B that is the disk of the first modification includes an upper layer portion 13u that is a protrusion, and a peripheral portion 13p around the upper layer portion 13u.

The front surface 13s of the upper layer portion 13u in the satellite disk 13B has a concave shape in which the center portion is recessed. That is, the front surface 13s has a concave portion that becomes deeper from the outer peripheral portion toward the center portion.

In the susceptor 11B according to the first modification of the first preferred embodiment having such a configuration, similarly to the basic configuration, when the SiC wafer 14 is mounted on the three lift-up pins 15, a disk upper space S13B is formed between the front surface 13s of the upper layer portion 13u of the satellite disk 13B and the back surface of the SiC wafer 14 except for the formation region of the three lift-up pins 15.

The disk upper space S13B has a larger volume than the disk upper space S13 of the basic configuration as the formation depth increases from the outer periphery to the center portion of the SiC wafer 14 on the back surface side of the SiC wafer 14 as compared with the disk upper space S13.

The susceptor 11B of the first modification has effects similar to those of the susceptor 11 of the basic configuration, and further has the following unique effects.

Since the front surface 13s of the upper layer portion 13u of the satellite disk 13 in the susceptor 11B of the first modification has a concave shape in which the center portion is recessed, it is possible to form the disk upper space S13B larger than the disk upper space S13 of the basic configuration on the back surface side of the SiC wafer 14.

As a result, the susceptor 11B of the first modification can release a part of the source gas G1 to the relatively large disk upper space S13B via the groove 2 which is an annular groove, so that the flow of the source gas G1 to be released to the back surface side of the SiC wafer 14 can be made smoother.

### Second Modification

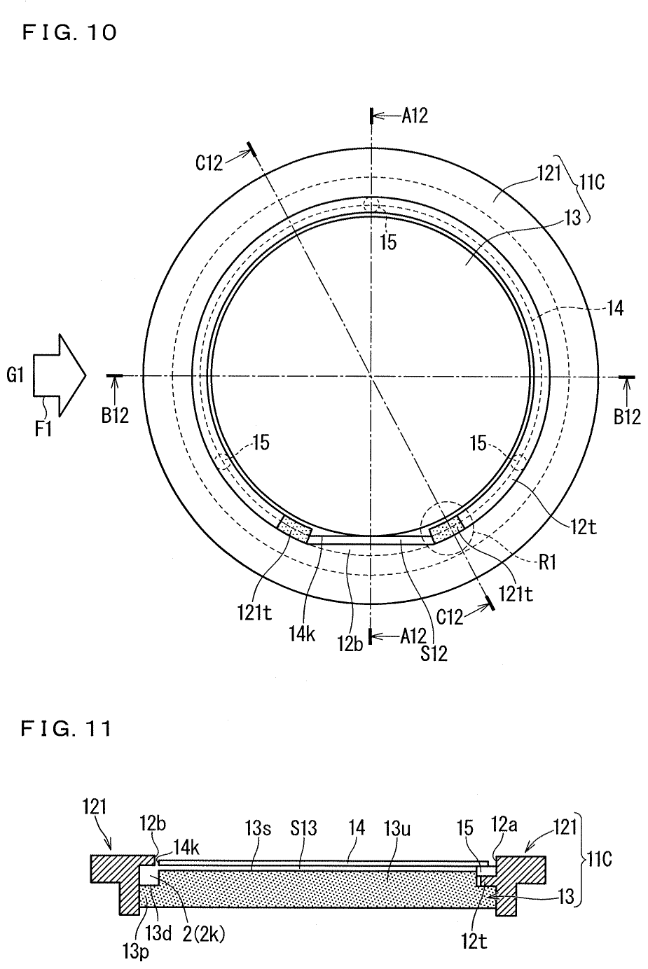

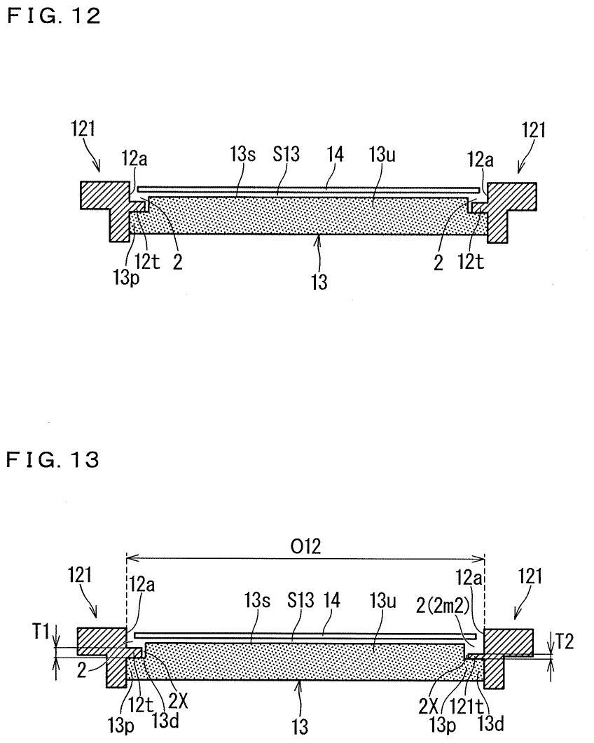

FIG. 10 is an explanatory view schematically illustrating a planar configuration of a susceptor 11C according to a second modification of the first preferred embodiment of the present disclosure. FIG. 11 is an explanatory view schematically illustrating a configuration of a cross section taken along line A12-A12 of FIG. 10, FIG. 12 is an explanatory view schematically illustrating a configuration of a cross section taken along line B12-B12 of FIG. 10, and FIG. 13 is an explanatory view schematically illustrating a configuration of a cross section taken along line C12-C12 of FIG. 10. Note that, in FIG. 10, planar structures of a ring 121 and a satellite disk 13, which are main components of the susceptor 11C, are schematically illustrated in an easily recognizable manner.

Similarly to the basic configuration, a mounting target of the susceptor 11C, which is the second modification of the wafer mounting apparatus of the first preferred embodiment, is the SiC wafer 14 having the orientation flat portion 14k.

Hereinafter, components similar to those of the susceptor 11 of the basic configuration illustrated in FIGS. 1 to 5 will be denoted by the same reference numerals, description thereof will be omitted as appropriate, and features of the susceptor 11C as the second modification will be mainly described.

As illustrated in FIGS. 10 to 13, the susceptor 11C includes, as main components, a combination of a satellite disk 13, which is a disk having a circular shape in plan view and a protruding cross section, and a ring 121 having a deformed T-shaped cross-sectional structure having a terrace portion 121t.

The ring 121 in the susceptor 11C of the second modification is characterized by further including two terrace portions 121t, which are auxiliary terrace portions protruding toward the side of the opening O12, in addition to the terrace portion 12t.

As illustrated in FIG. 10, the two terrace portions 121t, which are auxiliary terrace portions, are provided adjacent to both ends of the wall portion 12b. That is, the two terrace portions 121t are provided between the terrace portion 12t and the wall portion 12b in plan view.

As illustrated in FIG. 13, formation heights of back surfaces of the two terrace portions 121t coincide with the formation height of the back surface of the terrace portion 12t. Then, the terrace portion 12t has a terrace thickness T1 in the height direction, and the terrace portions 121t have a terrace thickness T2 (<T1) in the height direction. As described above, the terrace portions 121t, which are auxiliary terrace portions, are set to be thinner in the height direction than the terrace portion 12t.

As illustrated in FIG. 13, the ring 121 is mounted on the satellite disk 13 in a mode in which the terrace portion 12t and the terrace portions 121t are supported on the peripheral portion front surface 13d of the peripheral portion 13p of the satellite disk 13. Spaces above the terrace portions 121t are grooves 2m2 serving as a gas escape flow path.

That is, in the groove 2m, the terrace portion 121t is a bottom surface, the side surface of the upper layer portion 13u is one side surface, and the wall portion 12a is the other side surface.

The susceptor 11C of the second modification having such a configuration has effects similar to those of the susceptor 11 of the basic configuration, and further has the following unique effects.

In the susceptor 11C, which is the wafer mounting apparatus of the second modification, the ring 121 is mounted on the satellite disk 13 in a mode in which the terrace portion 12t and the terrace portions 121t are supported on the peripheral portion front surface 13d of the peripheral portion 13p of the satellite disk 13, so that the combination structure of the satellite disk 13 and the ring 121 can be achieved with good stability.

Furthermore, by setting the terrace portions 121t, which are auxiliary terrace portions, to be thinner in the height direction than the terrace portion 12t, the grooves 2m2, which are spaces above the terrace portions 121t, can be formed deeper than the groove 2, which is a space above the terrace portion 12t. That is, formation depths of the grooves 2m2, which are peripheral regions of both ends of the orientation flat portion 14k, can be made deeper than the formation depth of the groove 2 with the terrace portion 12t as a bottom surface.

As a result, the susceptor 11C of the second modification can minimize deterioration of the function of the groove 2m2 as a gas escape flow path for releasing the source gas G1 supplied to the periphery of the orientation flat portion 14k as a cutout portion to the disk upper space S13 on the back surface side of the SiC wafer 14.

### Second Preferred Embodiment

### (Basic Configuration)

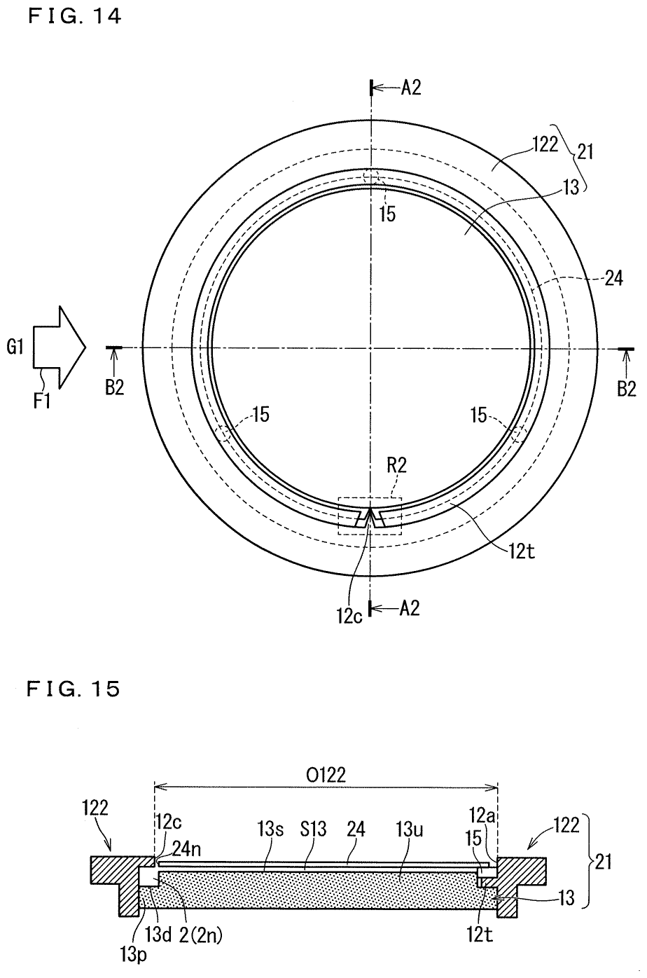

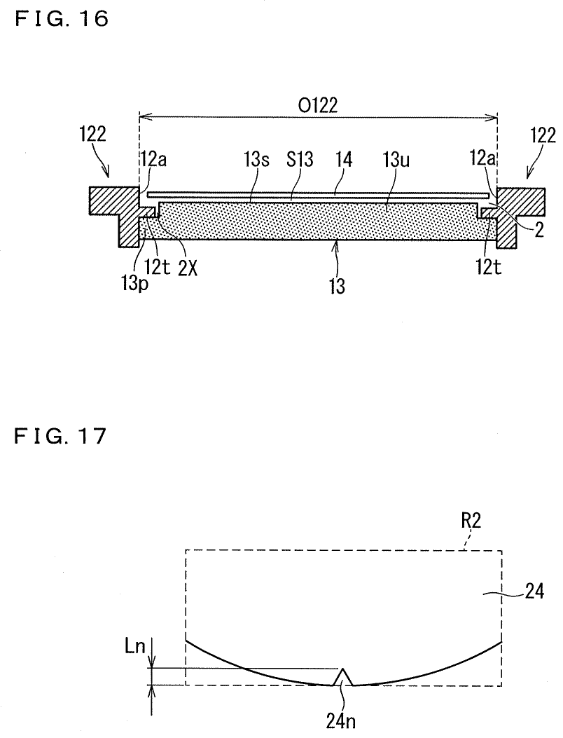

FIG. 14 is an explanatory view schematically illustrating a planar configuration of a susceptor 21, which is a basic configuration of a second preferred embodiment of the present disclosure. FIG. 15 is an explanatory view schematically illustrating a configuration of an A2-A2 cross section of FIG. 14, FIG. 16 is an explanatory view schematically illustrating a configuration of a B2-B2 cross section of FIG. 14, and FIG. 17 is an enlarged explanatory view illustrating a focused region R2 of FIG. 14. Note that, in FIG. 14, the planar structures of the ring 122 and the satellite disk 13, which are main components of the susceptor 21, are schematically illustrated in an easily recognizable manner.

A mounting target of the susceptor 21, which is the basic configuration of the wafer mounting apparatus according to the second preferred embodiment, is a SiC wafer 24 having a notch 24n having a notch length Ln (see FIG. 17). That is, the susceptor 21 of the second preferred embodiment is a wafer mounting apparatus on which the SiC wafer 24 having the notch 24n is mounted. The SiC wafer 24 is a semiconductor wafer having the notch 24n as a cutout portion.

Hereinafter, components similar to those of the susceptor 11 of the basic configuration of the first preferred embodiment illustrated in FIGS. 1 to 5 will be denoted by the same reference numerals, description thereof will be omitted as appropriate, and features of the susceptor 21 of the basic configuration of the second preferred embodiment will be mainly described.

As illustrated in FIGS. 14 to 17, the susceptor 21 includes, as main components, a combination of a satellite disk 13, which is a disk having a circular shape in plan view and a protruding cross section, and a ring 122 having a deformed T-shaped cross-sectional structure having a terrace portion 12t.

The ring 122 is provided with a wall portion 12a and a wall portion 12c on an upper side, and has an opening O122 with the wall portion 12a and the wall portion 12c as outer peripheries. The opening O122 has a shape approximate to the wafer shape of the SiC wafer 24, includes the SiC wafer 24 in plan view, and has a planar shape slightly larger than the SiC wafer 24.

The wall portion 12c of the ring 122 functions as a cutout-side protruding wall portion protruding toward a side of the opening O122 corresponding to the notch 24n, which is a cutout portion of the SiC wafer 24. As illustrated in FIG. 14, the wall portion 12c, which is the cutout-side protruding wall portion, is disposed so as to fill a part of the notch 24n without coming into contact with the SiC wafer 24, which is a semiconductor wafer.

As illustrated in FIG. 15, the wall portion 12c serving as the cutout-side protruding wall portion does not have a contact relationship with the peripheral portion front surface 13d of the peripheral portion 13p of the satellite disk 13.

The ring 122 further includes a terrace portion 12t protruding toward the side of the opening O122 in an intermediate region in the height direction, and as illustrated in FIG. 14, the terrace portion 12t does not overlap the wall portion 12c, which is the cutout-side protruding wall portion, in plan view.

The ring 122 is mounted on the satellite disk 13 in such a manner that the terrace portion 12t is supported on the peripheral portion front surface 13d of the peripheral portion 13p of the satellite disk 13.

In the susceptor 21, which is the basic configuration of the second preferred embodiment, a front surface of the terrace portion 12t is a lift-up region for the three lift-up pins 15.

The three lift-up pins 15, which are a plurality of lift-up members each having the same height, are mounted on the front surface of the terrace portion 12t in the ring 122. The three lift-up pins 15 hold the SiC wafer 24 by supporting the SiC wafer 24 from a back surface.

As described above, the susceptor 21, which is the basic configuration of the second preferred embodiment, includes the ring 121, the satellite disk 13, and the three lift-up pins 15 as main components.

In the susceptor 21 of the second preferred embodiment having such a configuration, the SiC wafer 24 can be held by mounting the SiC wafer 24 on the three lift-up pins 15 so that the SiC wafer 24 fits within the opening O122 in plan view without being in contact with the ring 122. This state is the semiconductor wafer mounting state related to the SiC wafer 24.

During the semiconductor wafer mounting state related to the SiC wafer 24, the wall portion 12c, which is the cutout-side protruding wall portion, faces the notch 24n and is arranged so as to fill a part of the notch 24n.

Since the SiC wafer 24 mounted in this manner is disposed in the opening O122 in plan view without having a contact relationship with the ring 122, an annular gap is always formed between an outer peripheral surface of the SiC wafer 24 and the opening O122. In addition, since the opening O122 is formed to approximate the shape of the SiC wafer 24, the annular gaps are provided at a constant interval without bias. This annular gap also functions as a gas escape flow path.

When the SiC wafer 24 is mounted on the three lift-up pins 15, a disk upper space S13 is formed between the front surface 13s of the upper layer portion 13u of the satellite disk 13 and the back surface of the SiC wafer 24 except for a formation region of the three lift-up pins 15.

Furthermore, a groove 2, which is an annular groove having an annular shape along the outer periphery of the opening O122 in plan view, is formed between the upper layer portion 13u of the satellite disk 13 and the ring 122 on the back surface side of the SiC wafer 24.

The annular groove 2 has one side surface as a side surface of the upper layer portion 13u and the other side surface as the wall portion 12a. Then, the groove 2 formed in the formation region of the terrace portion 12t is a space above the terrace portion 12t with the terrace portion 12t as a bottom surface.

On the other hand, as illustrated in FIG. 15, in the region where the terrace portion 12t is not formed, the groove 2 immediately below the wall portion 12c is a groove 2n. The groove 2n is a space above the peripheral portion front surface 13d with the peripheral portion front surface 13d of the peripheral portion 13p as a bottom surface.

The terrace portion 12t of the ring 122 is provided so as not to have a contact relationship with the side surface of the upper layer portion 13u of the satellite disk 13. Therefore, an auxiliary groove 2X communicating with the groove 2 in the depth direction can be provided between the front end of the terrace portion 12t and the side surface of the upper layer portion 13u.

The lower surface of the wall portion 12c is positioned between the front surface of the ring 122 and the back surface of the SiC wafer 24 similarly to the wall portion 12b of the preferred embodiment, but is desirably positioned between the front surface and the back surface of the SiC wafer 24.

In the susceptor 21 of the second preferred embodiment, the lower surface of the wall portion 12c corresponding to the notch 24n of the SiC wafer 24 is aligned in height with the upper surfaces of the three lift-up pins 15 (the back surface of the SiC wafer 24). In addition, the ring 122 is configured so that the terrace portion 12t is not formed at a location corresponding to the notch 24n and a region in the vicinity thereof. Therefore, the groove 2n serving as a gas escape flow path for releasing the source gas G1 to the disk upper space S13 can be provided deeper than the groove 2 with the terrace portion 12t as a bottom surface.

When the susceptor 21 of the second preferred embodiment is applied to the semiconductor manufacturing apparatus 50 illustrated in FIG. 25, the satellite disk 183 is replaced with the susceptor 21 including the ring 122, the satellite disk 13, and the three lift-up pins 15, and the SiC wafer 184 is replaced with the SiC wafer 24.

In a case where the susceptor 21 of the second preferred embodiment illustrated in FIGS. 14 to 17 is applied to the semiconductor manufacturing apparatus 50 illustrated in FIG. 25, the source gas G1 is supplied from the outside of the rotating susceptor 132 in the planetary susceptor type CVD apparatus. When the notch 24n of the SiC wafer 24 approaches the injector 186 and the source gas G1 is supplied from the notch 24n side, a part of the source gas G1 flows into the disk upper space S13 through the gap space between the SiC wafer 24 and the wall portion 12c and the groove 2n.

As described above, since the groove 2n is formed deeper than the groove 2 with the terrace portion 12t as a bottom surface, the source gas G1 supplied above the notch 24n of the SiC wafer 24 can be smoothly released to the disk upper space S13 on the back surface side of the SiC wafer 24.

On the other hand, when the lower surface of the wall portion 12c is lower than the back surface of the SiC wafer 24, the wall portion 12c protrudes to the groove 2n and there is a concern that the function of the groove 2n as a gas escape flow path may be impaired, and thus the position of the lower surface of the wall portion 12c is set to be equal to or higher than the heights of the upper surfaces of the three lift-up pins 15 (back surface of the SiC wafer 24).

The susceptor 21, which is the basic configuration of the wafer mounting apparatus according to the second preferred embodiment of the present disclosure, achieves the semiconductor wafer mounting state related to the SiC wafer 24 by mounting the SiC wafer 24, which is a semiconductor wafer, on the three lift-up pins 15. Therefore, the disk upper space S13 can be provided between the back surface of the SiC wafer 24 and the front surface 13s of the satellite disk 13.

Furthermore, in the susceptor 21 of the second preferred embodiment, the groove 2 which is an annular groove is formed between the upper layer portion 13u of the satellite disk 13 and the ring 122 on the back surface side of the SiC wafer 24 during the semiconductor wafer mounting state.

Therefore, when the source gas G1 is supplied above the front surface of the SiC wafer 24 in the semiconductor wafer mounting state, a part of the source gas G1 can be intentionally released to the disk upper space S13 on the back surface side of the SiC wafer 24 through the annular gap and the groove 2 along the outer periphery of the SiC wafer 24.

As a result, when the susceptor 21 according to the second preferred embodiment executes the epitaxial growth process to form an epitaxial growth layer on the front surface of the SiC wafer 24 in the semiconductor wafer mounting state, the susceptor can suppress the occurrence of an epi-crown phenomenon in which the epi thickness of the epitaxial growth layer locally increases. This epi-crown phenomenon occurs mainly on the outer peripheral portion on the front surface of the SiC wafer 24.

As a result, the susceptor 21 according to the second preferred embodiment has an effect of being able to form an epitaxial layer having excellent in-plane uniformity on the front surface of the SiC wafer 24 in the semiconductor wafer mounting state. Note that an epi thickness and a carrier concentration (impurity concentration) are included as indices of in-plane uniformity.

Furthermore, since the height of the uppermost surface of the ring 122 can be arbitrarily set, the wafer susceptor top distance DT, which is the difference in height between the front surface of the SiC wafer 24 mounted on the three lift-up pins 15 and the uppermost surface of the ring 122, can be set to an optimum length that does not cause an extreme decrease in the epi thickness at the outer peripheral portion of the front surface of the SiC wafer 24.

Since the opening O122 of the ring 122 is shaped to include the SiC wafer 24 and has a larger formation area than the SiC wafer 24, the SiC wafer 24 can be reliably mounted on the three lift-up pins 15 without being brought into contact with the ring 122 including the wall portion 12c serving as the cutout-side protruding wall portion.

Furthermore, by making the opening O122 have an approximate shape conforming to the shape of the SiC wafer 24, the susceptor 21 according to the second preferred embodiment can effectively suppress the occurrence of epi-crown.

In addition, since the wall portion 12c, which is the cutout-side protruding wall portion, does not have a contact relationship with the peripheral portion front surface 13d of the peripheral portion 13p of the satellite disk 13, the function as the gas escape flow path of the groove 2n formed below the wall portion 12c is not deteriorated.

In the susceptor 21 of the second preferred embodiment, since the formation height of the lower surface of the wall portion 12c, which is the cutout-side protruding wall portion, is set to be equal to or higher than the formation heights of the upper surfaces of the three lift-up pins 15, the function of the groove 2n as the gas escape flow path is not deteriorated.

In addition, in the susceptor 21 of the second preferred embodiment, the upper surface of the wall portion 12c, which is the cutout-side protruding wall portion, is provided to be a part of the upper surface of the ring 122. That is, the formation height of the upper surface of the wall portion 12c coincides with the formation height of the upper surface of the ring 122. Therefore, the groove 2n as the gas escape flow path can be formed below the wall portion 12c having a sufficient thickness.

Furthermore, the wall portion 12c, which is the cutout-side protruding wall portion, faces the SiC wafer 24 in the semiconductor wafer mounting state and is disposed so as to fill a part of the notch 24n without coming into contact with the SiC wafer 24, whereby the amount of the source gas G1 flowing through the groove 2n via the notch 24n can be limited not to exceed an allowable upper limit amount. This is because if the source gas G1 exceeding the allowable upper limit amount flows into the groove 2n via the notch 24n, the source gas G1 supplied to the front surface of the SiC wafer 24 may fall below an appropriate amount.

Therefore, the susceptor 21 of the second preferred embodiment can supply an appropriate amount of the source gas G1 to the front surface of the SiC wafer 24 having the notch 24n.

As described above, the susceptor 21, which is the basic configuration of the second preferred embodiment, has effects similar to those of the susceptor 11, which is the basic configuration of the first preferred embodiment, except that the mounting target is changed from the SiC wafer 14 to the SiC wafer 24.

Also in the second preferred embodiment, modifications similar to the first and second modifications of the first preferred embodiment illustrated in FIGS. 6 to 13 can be configured.

That is, as a first modification, the front surface 13s of the upper layer portion 13u of the satellite disk 13 may be changed to a concave shape in which the center portion is recessed. Furthermore, as a second modification, two auxiliary terrace portions may be provided between the terrace portion 12t and the wall portion 12c in plan view.

Note that, as illustrated in FIG. 17, since the notch length Ln, which is the length of the notch 24n in the radial direction, is shorter than the formation length of the orientation flat portion 14k, it is assumed that the possibility that epi-crown occurs is relatively low.

In that case, it is conceivable that the epi-crown phenomenon can be suppressed only by not providing the wall portion 12c and not forming the notch 24n and the terrace portion 12t in the vicinity thereof. When this possibility is satisfied, a configuration in which the formation of the wall portion 12c is omitted is conceivable.

However, in a case where the wall portion 12c is not formed in the ring 121, when the SiC wafer 24 is mounted, it may be difficult to align the notch 24n of the SiC wafer 24 with a terrace non-formation region where the terrace portion 12t is not formed. Therefore, it is desirable to form the wall portion 12c on the ring 121. If the wall portion 12c is not formed, the above-described difficulty of alignment can be reduced by ensuring a large terrace non-formation region.

In the susceptor 21, which is the basic configuration of the second preferred embodiment, the terrace portion 12t is supported from below on the front surface of the peripheral portion 13p of the satellite disk 13, but if there is no problem in strength, a plurality of partial terrace portions may be discretely provided instead of the terrace portion 12t continuously formed as in the first preferred embodiment.

### Third Preferred Embodiment

### (Basic Configuration)

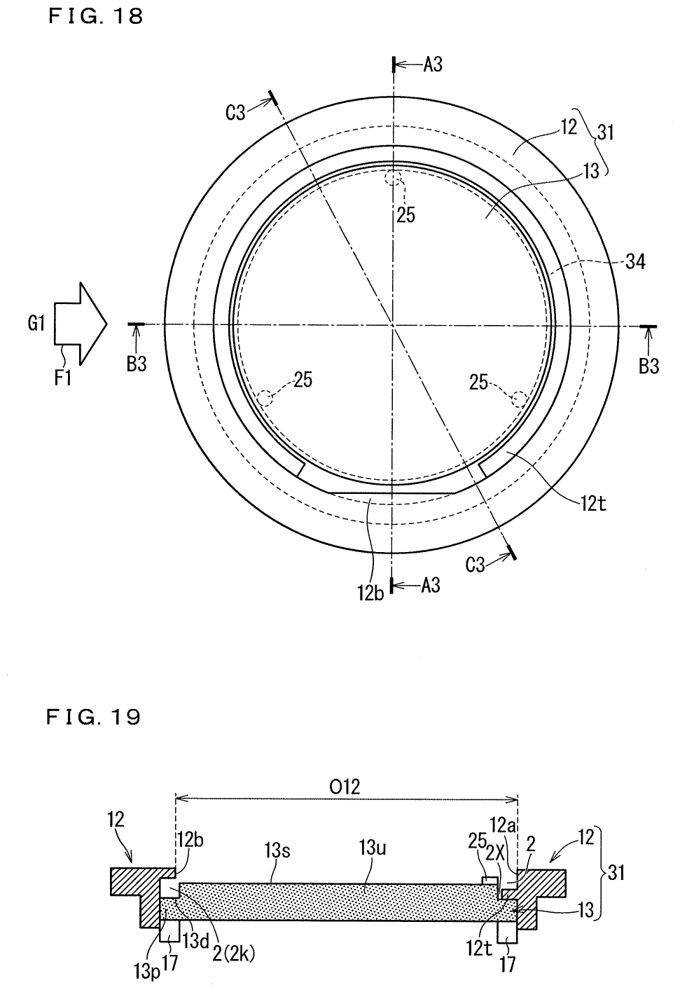

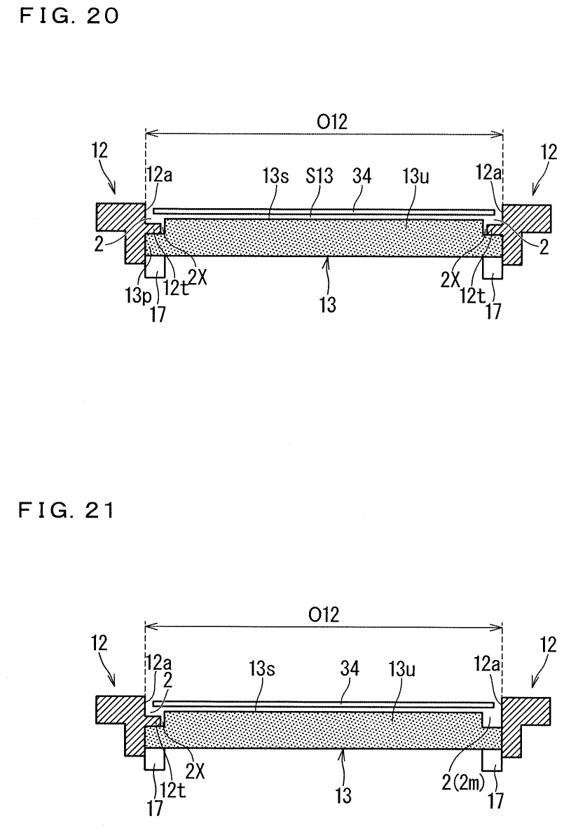

FIG. 18 is an explanatory view schematically illustrating a planar configuration of a susceptor 31, which is a basic configuration of a third preferred embodiment of the present disclosure. FIG. 19 is an explanatory view schematically illustrating a configuration of an A3-A3 cross section of FIG. 18, FIG. 20 is an explanatory view schematically illustrating a configuration of a B3-B3 cross section of FIG. 18, and FIG. 21 is an explanatory view schematically illustrating a configuration of a C₃-C₃ cross section of FIG. 18. In FIG. 18, the planar structures of the ring 12 and the SiC wafer 34 as a mounting target, which are main components of the susceptor 31, are schematically illustrated in an easily recognizable manner.

A mounting target of the susceptor 31, which is the basic configuration of the wafer mounting apparatus according to the third preferred embodiment, is a SiC wafer 34. In FIG. 18, the SiC wafer 34 is formally illustrated in a circular shape in plan view, but the SiC wafer 34 illustrates the SiC wafer 14 or the SiC wafer 24. That is, the mounting target of the susceptor 31 of the third preferred embodiment is the SiC wafer 14 having the orientation flat portion 14k or the SiC wafer 24 having the notch 24n.

Hereinafter, components similar to those of the susceptor 11 of the basic configuration of the first preferred embodiment illustrated in FIGS. 1 to 5 will be denoted by the same reference numerals, description thereof will be omitted as appropriate, and features of the susceptor 31 of the basic configuration of the third preferred embodiment will be mainly described.

Note that FIGS. 18 to 21 illustrate the ring 12 assuming a case where the SiC wafer 34 is the SiC wafer 14. Therefore, when the SiC wafer 34 is the SiC wafer 24, the ring 122 illustrated in FIGS. 14 to 16 is used instead of the ring 12.

Hereinafter, for convenience of description, the susceptor 31 of the third preferred embodiment will be described assuming that the SiC wafer 34 is the SiC wafer 14.

As illustrated in FIGS. 18 to 21, the susceptor 31 includes, as main components, a combination of a satellite disk 13, which is a disk having a circular shape in plan view and a protruding cross section, and a ring 12.

The satellite disk 13, which is a disk of the basic configuration, includes an upper layer portion 13u, which is a protrusion, and includes a peripheral portion 13p around the upper layer portion 13u.

Three lift-up pins 25, which are a plurality of lift-up members each having the same height, are mounted on the front surface 13s of the upper layer portion 13u of the satellite disk 13. The three lift-up pins 25 hold the SiC wafer 34 by supporting the SiC wafer 34 from the back surface.

In the susceptor 31 of the third preferred embodiment, the front surface 13s of the upper layer portion 13u of the satellite disk 13 is a lift-up region.

Furthermore, an annular support member 17 is disposed below the outer peripheral portion of the back surface of the satellite disk 13 in plan view, and the satellite disk 13 is supported by the support member 17.

As described above, the susceptor 31, which is the basic configuration of the third preferred embodiment includes the ring 12, the satellite disk 13, the three lift-up pins 25, and the support member 17 as main components.

In the susceptor 31 of the third preferred embodiment having such a configuration, the SiC wafer 34 can be held by mounting the SiC wafer 34 on the three lift-up pins 25 so that the SiC wafer 34 fits within the opening O12 in plan view without being in contact with the ring 12. This state is the semiconductor wafer mounting state related to the SiC wafer 34.

When the SiC wafer 34 is mounted on the three lift-up pins 25, a disk upper space S13 is formed between the front surface 13s of the upper layer portion 13u of the satellite disk 13 and the back surface of the SiC wafer 34 except for a formation region of the three lift-up pins 25.

Furthermore, a groove 2, which is an annular groove having an annular shape along the outer periphery of the opening O12 in plan view, is formed between the upper layer portion 13u of the satellite disk 13 and the ring 12 on the back surface side of the SiC wafer 34.

The annular groove 2 has one side surface as a side surface of the upper layer portion 13u and the other side surface as the wall portion 12a. Then, the groove 2 formed in the formation region of the terrace portion 12t is a space above the terrace portion 12t with the terrace portion 12t as a bottom surface.

On the other hand, as illustrated in FIG. 19, in the region where the terrace portion 12t is not formed, the groove 2 immediately below the wall portion 12b is a groove 2k, and as illustrated in FIG. 21, the groove 2 positioned immediately below both end peripheral regions of the wall portion 12b is a groove 2m.

The terrace portion 12t of the ring 12 is provided so as not to have a contact relationship with the side surface of the upper layer portion 13u of the satellite disk 13. Therefore, an auxiliary groove 2X communicating with the groove 2 in the depth direction can be provided between the front end of the terrace portion 12t and the side surface of the upper layer portion 13u.

When the susceptor 31 of the third preferred embodiment is applied to the semiconductor manufacturing apparatus 50 illustrated in FIG. 25, the satellite disk 183 is replaced with the susceptor 31 including the ring 12, the satellite disk 13, the three lift-up pins 25, and the support member 17, and the SiC wafer 184 is replaced with the SiC wafer 34.

The susceptor 31, which is the basic configuration of the wafer mounting apparatus according to the third preferred embodiment of the present disclosure, achieves the semiconductor wafer mounting state related to the SiC wafer 34 by mounting the SiC wafer 34, which is a semiconductor wafer, on the three lift-up pins 25, which are a plurality of lift-up members. Therefore, the disk upper space S13 can be provided between the back surface of the SiC wafer 34 and the front surface 13s of the satellite disk 13.

Furthermore, in the susceptor 31 of the third preferred embodiment, in the semiconductor wafer mounting state, the groove 2 which is an annular groove is formed between the upper layer portion 13u of the satellite disk 13 and the ring 12 on the back surface side of the SiC wafer 34.

As a result, the susceptor 31 according to the third preferred embodiment has an effect of being able to form an epitaxial layer having excellent in-plane uniformity on the front surface of the SiC wafer 34 in the semiconductor wafer mounting state, similarly to first and second preferred embodiments. Note that an epi thickness and a carrier concentration (impurity concentration) are included as indices of in-plane uniformity.

As described above, the susceptor 31, which is the basic configuration of the third preferred embodiment has effects similar to those of the susceptors 11 and 21, which are the basic configurations of the first preferred embodiment and the second preferred embodiment, and further has the following unique effects.

The susceptor 31 of the third preferred embodiment has the front surface 13s of the upper layer portion 13u of the satellite disk 13 as a lift-up region, and can stably support the SiC wafer 34 by the three lift-up pins 25 mounted on the front surface 13s.

Furthermore, in the susceptor 31 of the third preferred embodiment, the support member 17 that supports the satellite disk 13 from the back surface can suppress the phenomenon that the satellite disk 13 on which the SiC wafer 34 is mounted warps via the three lift-up pins 25.

Also in the third preferred embodiment, modifications similar to the first and second modifications of the first preferred embodiment can be configured.

That is, as a first modification, the front surface 13s of the upper layer portion 13u of the satellite disk 13 may be changed to a concave shape in which the center portion is recessed. However, in order to stably support the SiC wafer 34, it is desirable that the region on which the three lift-up pins 25 are mounted is flat on the front surface 13s of the upper layer portion 13u.

Furthermore, as a second modification, two auxiliary terrace portions may be provided between the terrace portion 12t and the wall portion 12b (wall portion 12c) in plan view.

### Fourth Preferred Embodiment

### (Basic Configuration)

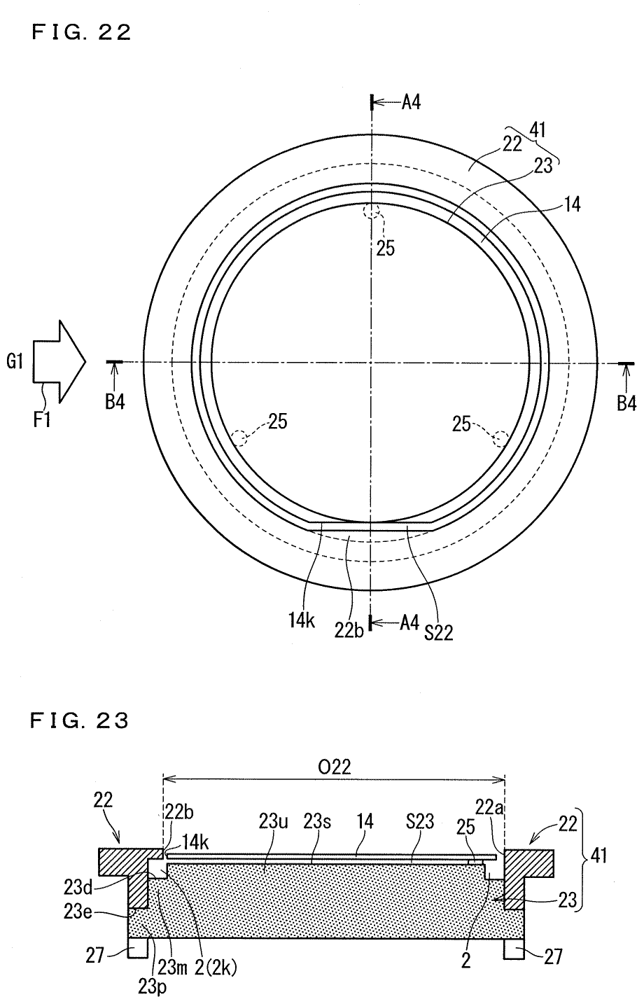

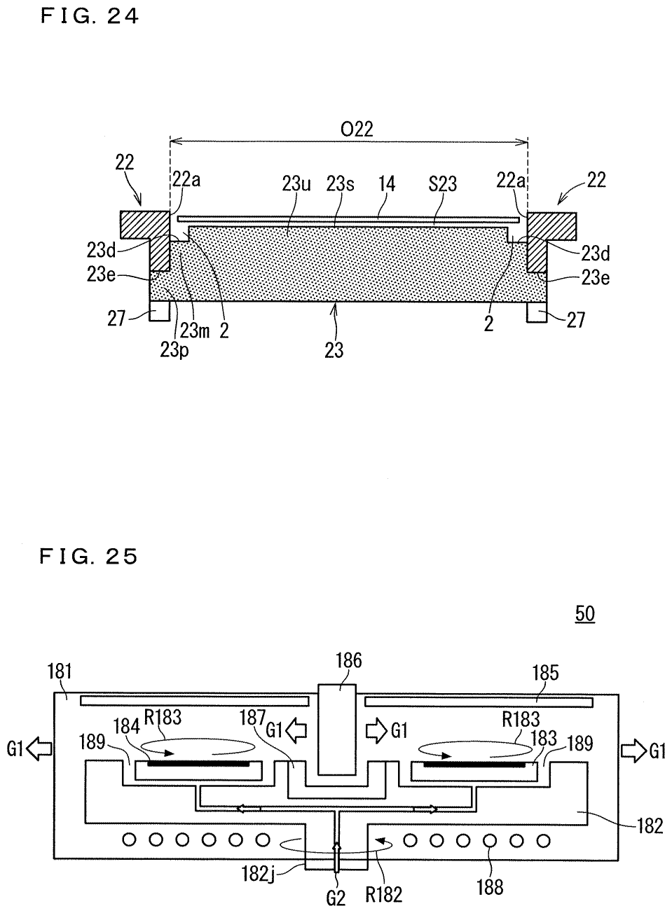

FIG. 22 is an explanatory view schematically illustrating a planar configuration of a susceptor 41, which is a basic configuration of the fourth preferred embodiment of the present disclosure. FIG. 23 is an explanatory view schematically illustrating a configuration of an A4-A4 cross section of FIG. 22, and FIG. 24 is an explanatory view schematically illustrating a configuration of a B4-B4 cross section of FIG. 22. Note that, in FIG. 22, the planar structures of a ring 22 and a satellite disk 23, which are main components of the susceptor 41, are schematically illustrated in an easily recognizable manner.

A mounting target of the susceptor 41, which is the basic configuration of the wafer mounting apparatus according to the fourth preferred embodiment, is the SiC wafer 14 having the orientation flat portion 14k. That is, the susceptor 41 of the fourth preferred embodiment is a wafer mounting apparatus on which the SiC wafer 14 having the orientation flat portion 14k is mounted.

Hereinafter, components similar to those of the susceptor 11 of the basic configuration of the first preferred embodiment illustrated in FIGS. 1 to 5 will be denoted by the same reference numerals, description thereof will be omitted as appropriate, and features of the susceptor 41 of the basic configuration of the fourth preferred embodiment will be mainly described.

As illustrated in FIGS. 22 to 24, the susceptor 41 includes, as main components, a combination of the satellite disk 23, which is a disk having a circular shape in plan view and a protruding cross section, and the ring 22.

The ring 22 is provided with a wall portion 22a and a wall portion 22b serving as inner peripheral surfaces. That is, in the ring 22, the wall portion 22b is selectively provided as a part of the inner peripheral surface of the ring 22, and the wall portion 22a serving as a uniform inner peripheral surface is provided in a region where the wall portion 22b is not provided.

The ring 22 has an opening O22 with the wall portion 22a and the wall portion 22b as outer peripheries. The opening O22 has a shape approximate to the wafer shape of the SiC wafer 14, includes the SiC wafer 14 in plan view, and has a planar shape slightly larger than the SiC wafer 14.

The wall portion 22b of the ring 22 functions as a cutout-side protruding wall portion protruding toward a side of the opening O22 corresponding to the orientation flat portion 14k which is a cutout portion of the SiC wafer 14. As illustrated in FIG. 22, the wall portion 22b is provided in parallel with the orientation flat portion 14k in plan view, and a gap space S22 in which a length in a lateral direction is a constant interval exists between the wall portion 22b and the orientation flat portion 14k.

The satellite disk 23, which is a disk of the basic configuration, includes an upper layer portion 23u which is a protrusion, includes an intermediate peripheral portion 23m which is a first peripheral portion around the upper layer portion 23u, and includes an outermost peripheral portion 23p which is a second peripheral portion around the intermediate peripheral portion 23m. In the satellite disk 23, the formation height decreases in the order of a front surface 23s of the upper layer portion 23u, an intermediate peripheral portion front surface 23d of the intermediate peripheral portion 23m, and an outermost peripheral portion front surface 23e of the outermost peripheral portion 23p.

The ring 22 is mounted on the satellite disk 23 in such a manner that a bottom surface of the ring 22 is supported on the outermost peripheral portion front surface 23e of the outermost peripheral portion 23p, which is the second peripheral portion of the satellite disk 23, along the entire circumference of the opening O22.

As illustrated in FIG. 23, the wall portion 22b serving as the cutout-side protruding wall portion does not have a contact relationship with the intermediate peripheral portion front surface 23d of the intermediate peripheral portion 23m of the satellite disk 23.

In the susceptor 41 having the mechanism configuration of the fourth preferred embodiment, the front surface 23s of the upper layer portion 23u is a lift-up region for the three lift-up pins 25.

The three lift-up pins 25 each having the same height are mounted on the front surface 23s of the upper layer portion 23u of the satellite disk 23. The three lift-up pins 25 hold the SiC wafer 14 by supporting the SiC wafer 14 from the back surface.

Furthermore, an annular support member 27 is disposed below the outer peripheral portion of the back surface of the satellite disk 23 in plan view, and the satellite disk 23 is supported by the support member 27.

As described above, the susceptor 41, which is the basic configuration of the fourth preferred embodiment includes the ring 22, the satellite disk 23, the three lift-up pins 25, and the support member 27 as main components.

In the susceptor 41 of the fourth preferred embodiment having such a configuration, the SiC wafer 14 can be held by mounting the SiC wafer 14 on the three lift-up pins 25 so that the SiC wafer 14 fits within the opening O22 in plan view without being in contact with the ring 22. This state is the semiconductor wafer mounting state related to the SiC wafer 14.

During the semiconductor wafer mounting state related to the SiC wafer 14, the wall portion 22b, which is the cutout-side protruding wall portion, and the orientation flat portion 14k are in a positional relationship of facing each other via the gap space S22 at a constant interval.

When the SiC wafer 14 is mounted on the three lift-up pins 25, a disk upper space S23 is formed between the front surface 23s of the upper layer portion 23u of the satellite disk 23 and the back surface of the SiC wafer 14 except for a formation region of the three lift-up pins 25.

Furthermore, a groove 2, which is an annular groove having an annular shape along the outer periphery of the opening O22 in plan view, is formed between the upper layer portion 23u of the satellite disk 23 and the ring 12 on the back surface side of the SiC wafer 14.

The annular groove 2 has one side surface as a side surface of the upper layer portion 23u and the other side surface as a wall portion 12a. As illustrated in FIG. 23, the groove 2 immediately below the wall portion 12b is a groove 2k.

When the susceptor 41 of the fourth preferred embodiment is applied to the semiconductor manufacturing apparatus 50 illustrated in FIG. 25, the satellite disk 183 is replaced with the susceptor 41 including the ring 22, the satellite disk 23, the three lift-up pins 25, and the support member 27, and the SiC wafer 184 is replaced with the SiC wafer 14.

The susceptor 41, which is the basic configuration of the wafer mounting apparatus according to the fourth preferred embodiment of the present disclosure, achieves the semiconductor wafer mounting state related to the SiC wafer 14 by mounting the SiC wafer 14 on the three lift-up pins 25. Therefore, the disk upper space S23 can be provided between the back surface of the SiC wafer 14 and the front surface 23s of the satellite disk 23.

Furthermore, in the susceptor 41 of the fourth preferred embodiment, the groove 2 which is an annular groove is formed between the upper layer portion 23u of the satellite disk 23 and the ring 22 on the back surface side of the SiC wafer 14 during the semiconductor wafer mounting state.

As a result, the susceptor 41 according to the fourth preferred embodiment has an effect of being able to form an epitaxial layer having excellent in-plane uniformity on the front surface of the SiC wafer 14 in the semiconductor wafer mounting state, similarly to first to third preferred embodiments. Note that an epi thickness and a carrier concentration (impurity concentration) are included as indices of in-plane uniformity.

As described above, the susceptor 41, which is the basic configuration of the fourth preferred embodiment, has effects similar to those of the susceptors 11, 21, and 31, which are the basic configurations of the first to third preferred embodiments, and further has the following unique effects.

In the susceptor 41 of the fourth preferred embodiment, the ring 22 is mounted on the satellite disk 23 in such a manner that the bottom surface of the ring 22 is supported on the outermost peripheral portion front surface 23e of the outermost peripheral portion 23p, which is the second peripheral portion of the satellite disk 23, along the entire circumference of the opening O22. Therefore, in the susceptor 41 of the fourth preferred embodiment, a combination structure of the satellite disk 23 and the ring 22 can be achieved without affecting the SiC wafer 14.

Also in the fourth preferred embodiment, a modification similar to the first modification of the first preferred embodiment can be configured.

That is, as a first modification, the front surface 23s of the upper layer portion 23u of the satellite disk 23 may be changed to a concave shape in which the center portion is recessed. However, in order to stably support the SiC wafer 14, it is desirable that the region on which the three lift-up pins 25 are mounted is flat on the front surface 23s of the upper layer portion 23u.

Further, the mounting target of the susceptor 41 of the fourth preferred embodiment is the SiC wafer 14, but may be the SiC wafer 24 as in the susceptor 21 of the second preferred embodiment. In this case, in the ring 22, a wall portion having a structure similar to the wall portion 12c is provided instead of the wall portion 22b.

### <Application to Semiconductor Manufacturing Apparatus>

As described above, the semiconductor manufacturing apparatus 50 illustrated in FIG. 25 can be configured using the wafer mounting apparatus illustrated in the first to fourth preferred embodiments as a component.

When the susceptor 11 of the first preferred embodiment is applied to the semiconductor manufacturing apparatus 50, the satellite disk 183 is replaced with the susceptor 11 including the ring 12, the satellite disk 13, and the three lift-up pins 15, and the SiC wafer 184 is replaced with the SiC wafer 14.

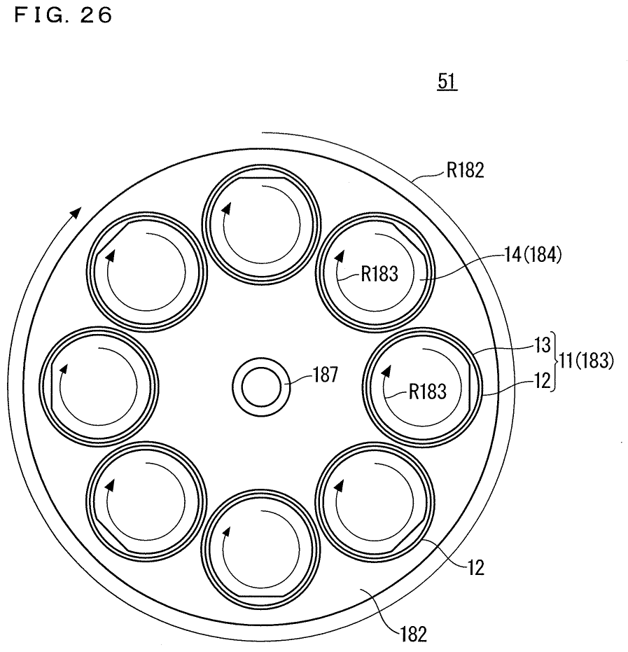

FIG. 26 is an explanatory view schematically illustrating a planar configuration of the semiconductor manufacturing apparatus 51. The semiconductor manufacturing apparatus 51 is a novel semiconductor manufacturing apparatus in which the semiconductor manufacturing apparatus 50 illustrated in FIG. 25 is applied to the susceptor 11 of the first preferred embodiment.

As illustrated in the drawing, the planetary susceptor 182 accommodates eight susceptors 11 each having a ring 12, a satellite disk 13, and three lift-up pins 15 as main components. That is, in the upper layer portion of the planetary susceptor 182, 8 susceptors 11 are arranged as 8 satellite disks 183 around the center part 187.

Each of the eight susceptors 11 is mounted with the SiC wafer 14 and rotates along the disk rotation direction R183. In addition, the planetary susceptor 182 itself also rotates along the susceptor rotation direction R182.

Note that, when the susceptor 21 of the second preferred embodiment is applied to the semiconductor manufacturing apparatus 50, the satellite disk 183 is replaced with the susceptor 21 including the ring 122, the satellite disk 13, and the three lift-up pins 15, and the SiC wafer 184 is replaced with the SiC wafer 24.

When the susceptor 31 of the third preferred embodiment is applied to the semiconductor manufacturing apparatus 50, the satellite disk 183 is replaced with the susceptor 31 including the ring 12, the satellite disk 13, the three lift-up pins 25, and the support member 17, and the SiC wafer 184 is replaced with the SiC wafer 34.

When the susceptor 41 of the fourth preferred embodiment is applied to the semiconductor manufacturing apparatus 50, the satellite disk 183 is replaced with the susceptor 41 including the ring 22, the satellite disk 23, the three lift-up pins 25, and the support member 27, and the SiC wafer 184 is replaced with the SiC wafer 14.

The semiconductor manufacturing apparatus 51 including any one of the wafer mounting apparatuses of the first to fourth preferred embodiments as a component is a novel semiconductor manufacturing apparatus. Note that both the SiC wafer 14 and the SiC wafer 24 are semiconductor wafers containing silicon carbide as a constituent material.

The semiconductor manufacturing apparatus 51 includes an induction heating coil 188 as a heating mechanism for heating a semiconductor wafer in the semiconductor wafer mounting state.

The novel semiconductor manufacturing apparatus 51 can form an epitaxial layer containing silicon carbide on the front surface of the SiC wafer 14 with good in-plane uniformity by supplying the source gas G1 for epitaxial growth above the front surface of the SiC wafer 14 in a state where the SiC wafer 14 in the semiconductor wafer mounting state is heated by the induction heating coil 188 as a heating mechanism. Note that an epi thickness and a carrier concentration (impurity concentration) are included as indices of in-plane uniformity.

### <Method of Manufacturing Semiconductor Device and Semiconductor Device Manufactured by Method of Manufacturing>

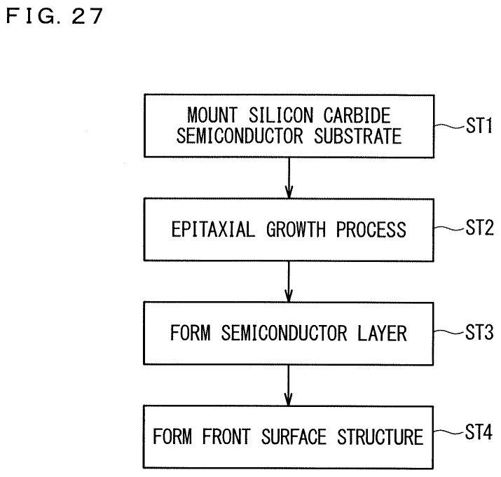

FIG. 27 is a flowchart illustrating a processing procedure of a method of manufacturing a semiconductor device using the novel semiconductor manufacturing apparatus 51. Hereinafter, a method of manufacturing a semiconductor device using the semiconductor manufacturing apparatus 51 to which the susceptor 11 of the first preferred embodiment is applied will be described.

In step ST1, the SiC wafer 14 as a silicon carbide semiconductor substrate is mounted on the three lift-up pins 15 by the susceptor 11.

That is, in step ST1, the SiC wafer 14 is mounted on the three lift-up pins 15 so that the SiC wafer 14 fits in the opening O12 in plan view without being in contact with the ring 12, thereby achieving the semiconductor wafer mounting state regarding the SiC wafer 14.

In step ST2, the epitaxial growth process is performed on the front surface of the SiC wafer 14 in the semiconductor wafer mounting state. That is, the source gas G1 for epitaxial growth is supplied to the front surface of the SiC wafer 14, and the SiC wafer 14 is heated by the induction heating coil 188 as a heating mechanism.

As a result, an epitaxial layer is formed on the front surface of the SiC wafer 14 in the semiconductor wafer mounting state.

Thereafter, in step ST3, a semiconductor layer for element formation is formed in the epitaxial layer, and then in step ST4, a front surface structure for element formation is formed on the semiconductor layer for element formation.

As a result, a semiconductor element can be manufactured by the semiconductor layer and the front surface structure of the element formation.

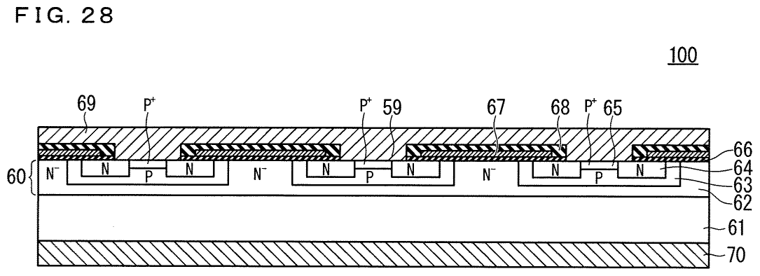

FIG. 28 is a cross-sectional view illustrating a cross-sectional structure of a semiconductor device 100 as an example of a semiconductor device manufactured by the method of manufacturing the semiconductor device illustrated in FIG. 27.

As illustrated in the drawing, an N⁻ epitaxial layer 62 is provided as an epitaxial layer on the front surface of the SiC substrate 61 corresponding to the SiC wafer 14. A P base layer 63 is selectively provided in an upper layer portion of the N⁻ epitaxial layer 62, an N source layer 64 is selectively provided in a front surface of the P base layer 63, and a P⁺ contact layer 65 is provided between N source layers 64 and 64 in the front surface of the P base layer 63.

The gate electrode 67 is formed via a gate oxide film 66 between the pair of N source layers 64 and 64 formed in the different P base layers 63 and adjacent to each other. The gate electrode 67 is formed from above the N source layer 64 provided in the front surface of one P base layer 63 to above the one P base layer 63, above the N epitaxial layer 62, above the other P base layer 63, and above the N source layer 64 provided in the front surface of the other P base layer 63. An interlayer insulating film 68 is provided to cover the gate oxide film 66 and the gate electrode 67.

Such a combination of the gate oxide film 66, the gate electrode 67, and the interlayer insulating film 68 is formed at a plurality of locations. Therefore, the semiconductor device 100 includes a plurality of gate oxide films 66, a plurality of gate electrodes 67, and a plurality of interlayer insulating films 68. Then, a source electrode 69 is provided on the entire surface of the N⁻ epitaxial layer 62 including the plurality of interlayer insulating films 68, and a drain electrode 70 is provided on a back surface of the SiC substrate 61.

Hereinafter, a process of manufacturing the semiconductor device 100 illustrated in FIG. 28 by the method of manufacturing the semiconductor device illustrated in FIG. 27 will be described.

The processing in step ST1 is processing of mounting the SiC wafer 14 to be the SiC substrate 61 finally on the susceptor 11.

The processing in step ST2 is processing of supplying the source gas G1 for epitaxial growth onto the front surface of the SiC wafer 14 mounted on the semiconductor manufacturing apparatus 51 and heating the SiC wafer 14 by the induction heating coil 188.

As a result, the epitaxial growth process is performed on the front surface of the SiC substrate 61, and the N⁻ epitaxial layer 62 to be an epitaxial layer is formed on the front surface of the SiC substrate 61. Here, the concentration of the n-type impurity contained in the SiC substrate 61 and the N⁻ epitaxial layer 62 is appropriately selected according to the withstand voltage of the semiconductor device to be manufactured.

Next, a semiconductor layer for element formation is formed in the N⁻ epitaxial layer 62. The P base layer 63, the N source layer 64, and the P⁺ contact layer 65 can each be formed by implanting ions of p-type impurities and n-type impurities into the N⁻ epitaxial layer 62 and diffusing the implanted ions in the N⁻ epitaxial layer 62 by a heat treatment or the like.

The P base layer 63, the N source layer 64, and the P⁺ contact layer 65 serve as semiconductor layers for element formation. That is, the process of step ST3 is a process of forming the P base layer 63, the N source layer 64, and the P⁺ contact layer 65.

Next, the gate oxide film 66, the gate electrode 67, and the interlayer insulating film 68 are selectively formed on the front surface of the N⁻ epitaxial layer 62 including the P base layer 63, the N source layer 64, and the P⁺ contact layer 65.

First, the SiC wafer 14 is heated in an atmosphere containing oxygen to form the gate oxide film 66 formed by SiO₂ on the upper surface of the semiconductor layer for element formation. Then, polysilicon doped with n-type or p-type impurities is deposited on the gate oxide film 66 using a chemical vapor deposition (CVD) method or the like to form the gate electrode 67.

Thereafter, the interlayer insulating film 68 is formed on the gate electrode 67. A constituent material of the interlayer insulating film 68 is, for example, SiO₂ or tetraethyl orthosilicate (TEOS). Through such steps, the plurality of gate oxide films 66, the plurality of gate electrodes 67, and the plurality of source electrodes 69 are selectively formed.

Then, a mask process is performed on the upper surface of the interlayer insulating film 68, and a part of the interlayer insulating film 68 is etched through the opening of the resist to form a contact hole 59 penetrating the interlayer insulating film 68.

The contact hole 59 is formed on the front surfaces of the N source layer 64 and the P⁺ contact layer 65.

Next, a barrier metal (not illustrated) is formed in the contact hole 59 of the interlayer insulating film 68 and on the interlayer insulating film 68. The barrier metal is formed by depositing Ti, TiN, or the like by a physical vapor deposition (PVD) method or a CVD method.

Next, the source electrode 69 is formed on the barrier metal. The source electrode 69 can be formed by, for example, depositing an aluminum silicon alloy (Al—Si-based alloy) on a barrier metal using a PVD method such as sputtering or vapor deposition.

Next, the drain electrode 70 is formed on the back surface of the SiC substrate 61. The drain electrode 70 is formed by depositing an aluminum silicon alloy, titanium, or the like using a PVD method such as sputtering or vapor deposition, for example. In addition, the drain electrode 70 may be formed by laminating a plurality of metals such as an aluminum silicon alloy, titanium, nickel, or gold.

The front surface structure for element formation is the gate oxide film 66, the gate electrode 67, the interlayer insulating film 68, the source electrode 69, and the drain electrode 70. That is, the processing of step ST4 is processing of forming the gate oxide film 66, the gate electrode 67, the interlayer insulating film 68, the source electrode 69, and the drain electrode 70.

Note that, since a plurality of semiconductor devices 100, which are silicon carbide semiconductor devices, is produced in a matrix on one SiC wafer 14, one SiC wafer 14 is cut into individual semiconductor devices 100 by laser dicing or blade dicing to be formed into chips, and the semiconductor device 100 illustrated in FIG. 28 is completed.

As a result, it is possible to manufacture the semiconductor device 100 including a Metal-Oxide-Semiconductor Field Effect Transistor (NMOSFET) as a semiconductor element configured by a semiconductor layer for element formation and a front surface structure.

As described above, in the semiconductor device 100 manufactured by the method of manufacturing a semiconductor device using the semiconductor manufacturing apparatus 51 including the planetary susceptor 182, the N⁻ epitaxial layer 62 has high in-plane uniformity such as an epi thickness, and it is possible to suppress a structure having poor electrical characteristics in a step after the formation of the N⁻ epitaxial layer 62, so that productivity is improved.

In addition, since it is possible to suppress the occurrence of poor electrical characteristics when a semiconductor layer for element formation is formed by ion implantation or the like, it is possible to obtain the semiconductor device 100 having a highly reliable NMOSFET.

The method of manufacturing the semiconductor device illustrated in FIG. 27 includes at least the following steps (a) to (c).
Step (a) is a step of mounting the SiC wafer 14 (SiC substrate 61) on the three lift-up pins 15 so that the SiC wafer 14 fits in the opening O12 in plan view without being in contact with the ring 12, and achieving the semiconductor wafer mounting state related to the SiC wafer 14.
Step (b) is a step of supplying the source gas G1 for epitaxial growth to the front surface of the SiC wafer 14 in the semiconductor wafer mounting state.
Step (c) is a step of heating the SiC wafer 14 in the semiconductor wafer mounting state by the induction heating coil 188 as a heating mechanism.

Step (a) corresponds to step ST1 illustrated in FIG. 27, and steps (b) and (c) correspond to step ST2 illustrated in FIG. 27.

Therefore, after the execution of the above-described steps (a) to (c), the N⁻ epitaxial layer 62 illustrated in FIG. 28 is formed on the front surface of the SiC substrate 61 corresponding to the semiconductor wafer.

In the method of manufacturing a semiconductor device using the novel semiconductor manufacturing apparatus 51, by executing steps (a) to (c), the N⁻ epitaxial layer 62 to be an epitaxial layer containing silicon carbide can be formed with good in-plane uniformity on the front surface of the SiC wafer 14 in the semiconductor wafer mounting state. Note that an epi thickness and a carrier concentration (impurity concentration) are included as indices of in-plane uniformity.

That is, the in-plane uniformity of the N⁻ epitaxial layer 62 formed on the SiC wafer 14 in the semiconductor wafer mounting state can be enhanced by the semiconductor device manufacturing method using the novel semiconductor manufacturing apparatus 51.

In the semiconductor device 100 that is a semiconductor device manufactured by the method of manufacturing a semiconductor device using the novel semiconductor manufacturing apparatus 51, since the semiconductor layer for element formation is formed in the N⁻ epitaxial layer 62 layer having high in-plane uniformity, it is possible to improve the reliability of the NMOSFET that is a semiconductor element including the semiconductor layer for element formation.

Note that, in the present disclosure, each preferred embodiment can be freely combined, and each preferred embodiment can be appropriately modified or omitted within the scope of the disclosure.

Hereinafter, various aspects of the present disclosure will be collectively described as appendices.

### Appendix 1

A wafer mounting apparatus that mounts a semiconductor wafer having a cutout portion, the wafer mounting apparatus including:
a disk having a protruding upper layer portion;
a ring disposed on the disk and having an opening in a center;
a plurality of lift-up members that is arranged on a lift-up region provided on the disk or the ring and that supports the semiconductor wafer from a back surface, in which
the ring has a cutout-side protruding wall portion protruding toward the opening, and
in a semiconductor wafer mounting state in which the semiconductor wafer is mounted on the plurality of lift-up members so that the semiconductor wafer fits in the opening in plan view without being in contact with the ring,
the cutout-side protruding wall portion faces the cutout portion of the semiconductor wafer, a disk upper space is formed between a front surface of the upper layer portion of the disk and a back surface of the semiconductor wafer except for a formation region of the plurality of lift-up members, an annular groove is formed along an outer periphery of the opening in plan view between the upper layer portion of the disk and the ring on a side of the back surface of the semiconductor wafer, and a side surface of the upper layer portion of the disk is a side surface of the annular groove.

### Appendix 2

The wafer mounting apparatus according to appendix 1, in which
the disk has a peripheral portion around the upper layer portion, a front surface of the peripheral portion has a formation height lower than a front surface of the upper layer portion, and a step exists from the front surface of the peripheral portion to the front surface of the upper layer portion,
the ring has a terrace portion protruding toward a side of the opening, and the terrace portion does not overlap the cutout-side protruding wall portion in plan view,
the ring is mounted on the disk in such a manner that the terrace portion is supported on a front surface of the peripheral portion of the disk, and
a thickness of the terrace portion in a height direction is thinner than the step on the disk.

### Appendix 3

The wafer mounting apparatus according to appendix 2, in which
the plurality of lift-up members is mounted on a front surface of the terrace portion of the ring, and
the lift-up region includes a front surface region of the terrace portion.

### Appendix 4

The wafer mounting apparatus according to appendix 2 or 3, in which
the terrace portion does not have a contact relationship with a side surface of the upper layer portion.

### Appendix 5

The wafer mounting apparatus according to any one of appendices 2 to 4, in which
the opening is shaped to include the semiconductor wafer and has a larger formation area than the semiconductor wafer, and
the cutout-side protruding wall portion has no contact relationship with a front surface of the peripheral portion of the disk.

### Appendix 6

The wafer mounting apparatus according to appendix 5, in which
a formation height of a lower surface of the cutout-side protruding wall portion is set to be equal to or higher than a formation height of upper surfaces of the plurality of lift-up members.

### Appendix 7

The wafer mounting apparatus according to appendix 5 or 6, in which
an upper surface of the cutout-side protruding wall portion is a part of an upper surface of the ring.

### Appendix 8

The wafer mounting apparatus according to any one of appendices 1 to 7, in which
the upper layer portion of the disk has a recessed shape in which a center portion is recessed.

### Appendix 9

The wafer mounting apparatus according to appendix 3, in which
the ring further includes an auxiliary terrace portion protruding toward the side of the opening in addition to the terrace portion, and the auxiliary terrace portion is provided between the terrace portion and the cutout-side protruding wall portion in plan view, and has a thickness in a height direction smaller than that the thickness of the terrace portion, and
the ring is mounted on the disk in a mode in which the terrace portion and the auxiliary terrace portion are supported on a front surface of the peripheral portion of the disk.

### Appendix 10

The wafer mounting apparatus according to appendix 2, in which
the plurality of lift-up members is mounted on the upper layer portion of the disk, and
the lift-up region includes a front surface region of the upper layer portion.

### Appendix 11

The wafer mounting apparatus according to appendix 10, further including:
a support member that supports the disk from a back surface.

### Appendix 12

The wafer mounting apparatus according to appendix 1, in which
the disk includes a first peripheral portion around the upper layer portion and a second peripheral portion around the first peripheral portion, and a formation height decreases in order of a front surface of the upper layer portion, a front surface of the first peripheral portion, and a front surface of the second peripheral portion, and
the ring is mounted on the disk in such a manner that a bottom surface of the ring is supported on the front surface of the second peripheral portion of the disk along an entire circumference of the opening.

### Appendix 13

The wafer mounting apparatus according to any one of appendices 1 to 12, in which
the cutout portion includes an orientation flat portion, and
the cutout-side protruding wall portion is disposed to face the orientation flat portion via a gap at a constant interval in the semiconductor wafer mounting state.

### Appendix 14

The wafer mounting apparatus according to any one of appendices 1 to 12, in which
the cutout portion includes a notch, and
the cutout-side protruding wall portion is disposed so as to fill a part of the notch without coming into contact with the semiconductor wafer in the semiconductor wafer mounting state.

### Appendix 15

A semiconductor manufacturing apparatus including the wafer mounting apparatus according to any one of appendices 1 to 14, in which
the semiconductor wafer contains silicon carbide as a constituent material, and
the wafer mounting apparatus further includes:
a heating mechanism that heats the semiconductor wafer in the semiconductor wafer mounting state.

### Appendix 16

A method of manufacturing a semiconductor device using the wafer mounting apparatus according to any one of appendices 1 to 14, in which
the semiconductor wafer contains silicon carbide as a constituent material,
the wafer mounting apparatus further includes a heating mechanism that heats the semiconductor wafer,
the method includes the steps of:
(a) achieving the semiconductor wafer mounting state by mounting the semiconductor wafer on the plurality of lift-up members so that the semiconductor wafer fits in the opening in plan view without being in contact with the ring;
(b) supplying a source gas for epitaxial growth to a front surface of the semiconductor wafer in the semiconductor wafer mounting state; and
(c) heating the semiconductor wafer in the semiconductor wafer mounting state by the heating mechanism, and
after the steps (a) to (c) are performed, an epitaxial layer is formed on a front surface of the semiconductor wafer in the semiconductor wafer mounting state.

### Appendix 17

A semiconductor device including:
the epitaxial layer formed by the method of manufacturing a semiconductor device according to appendix 16; and
a semiconductor layer for element formation formed in the epitaxial layer.

While the disclosure has been shown and described in detail, the foregoing description is in all aspects illustrative and not restrictive. It is therefore understood that numerous modifications and variations can be devised.

What is claimed is:

1. A wafer mounting apparatus that mounts a semiconductor wafer having a cutout portion, the wafer mounting apparatus comprising:
a disk having a protruding upper layer portion;
a ring disposed on the disk and having an opening in a center;
a plurality of lift-up members that is arranged on a lift-up region provided on the disk or the ring and that supports the semiconductor wafer from a back surface, wherein
the ring has a cutout-side protruding wall portion protruding toward the opening, and
in a semiconductor wafer mounting state in which the semiconductor wafer is mounted on the plurality of lift-up members so that the semiconductor wafer fits in the opening in plan view without being in contact with the ring,
the cutout-side protruding wall portion faces the cutout portion of the semiconductor wafer, a disk upper space is formed between a front surface of the upper layer portion of the disk and a back surface of the semiconductor wafer except for a formation region of the plurality of lift-up members, an annular groove having an annular shape is formed along an outer periphery of the opening in plan view between the upper layer portion of the disk and the ring on a side of the back surface of the semiconductor wafer, and a side surface of the upper layer portion of the disk is a side surface of the annular groove.

2. The wafer mounting apparatus according to claim 1, wherein
the disk has a peripheral portion around the upper layer portion, a front surface of the peripheral portion has a formation height lower than a front surface of the upper layer portion, and a step exists from the front surface of the peripheral portion to the front surface of the upper layer portion,
the ring has a terrace portion protruding toward a side of the opening, and the terrace portion does not overlap the cutout-side protruding wall portion in plan view,
the ring is mounted on the disk in such a manner that the terrace portion is supported on a front surface of the peripheral portion of the disk, and
a thickness of the terrace portion in a height direction is thinner than the step on the disk.

3. The wafer mounting apparatus according to claim 2, wherein
the plurality of lift-up members is mounted on a front surface of the terrace portion of the ring, and
the lift-up region includes a front surface region of the terrace portion.

4. The wafer mounting apparatus according to claim 2, wherein
the terrace portion does not have a contact relationship with a side surface of the upper layer portion.

5. The wafer mounting apparatus according to claim 2, wherein
the opening is shaped to include the semiconductor wafer and has a larger formation area than the semiconductor wafer, and
the cutout-side protruding wall portion has no contact relationship with a front surface of the peripheral portion of the disk.

6. The wafer mounting apparatus according to claim 5, wherein
a formation height of a lower surface of the cutout-side protruding wall portion is set to be equal to or higher than a formation height of upper surfaces of the plurality of lift-up members.

7. The wafer mounting apparatus according to claim 5, wherein
an upper surface of the cutout-side protruding wall portion is a part of an upper surface of the ring.

8. The wafer mounting apparatus according to claim 1, wherein
the upper layer portion of the disk has a recessed shape in which a center portion is recessed.

9. The wafer mounting apparatus according to claim 3, wherein
the ring further includes an auxiliary terrace portion protruding toward the side of the opening in addition to the terrace portion, and the auxiliary terrace portion is provided between the terrace portion and the cutout-side protruding wall portion in plan view, and has a thickness in a height direction smaller than that the thickness of the terrace portion, and
the ring is mounted on the disk in a mode in which the terrace portion and the auxiliary terrace portion are supported on a front surface of the peripheral portion of the disk.

10. The wafer mounting apparatus according to claim 2, wherein
the plurality of lift-up members is mounted on the upper layer portion of the disk, and
the lift-up region includes a front surface region of the upper layer portion.

11. The wafer mounting apparatus according to claim 10, further comprising:
a support member that supports the disk from a back surface.

12. The wafer mounting apparatus according to claim 1, wherein
the disk includes a first peripheral portion around the upper layer portion and a second peripheral portion around the first peripheral portion, and a formation height decreases in order of a front surface of the upper layer portion, a front surface of the first peripheral portion, and a front surface of the second peripheral portion, and
the ring is mounted on the disk in such a manner that a bottom surface of the ring is supported on the front surface of the second peripheral portion of the disk along an entire circumference of the opening.

13. The wafer mounting apparatus according to claim 1, wherein
the cutout portion includes an orientation flat portion, and
the cutout-side protruding wall portion is disposed to face the orientation flat portion via a gap at a constant interval in the semiconductor wafer mounting state.

14. The wafer mounting apparatus according to claim 1, wherein
the cutout portion includes a notch, and
the cutout-side protruding wall portion is disposed so as to fill a part of the notch without coming into contact with the semiconductor wafer in the semiconductor wafer mounting state.

15. A semiconductor manufacturing apparatus comprising the wafer mounting apparatus according to claim 1, wherein
the semiconductor wafer contains silicon carbide as a constituent material, and
the wafer mounting apparatus further includes a heating mechanism that heats the semiconductor wafer in the semiconductor wafer mounting state.

16. A method of manufacturing a semiconductor device using the wafer mounting apparatus according to claim 1, wherein
the semiconductor wafer contains silicon carbide as a constituent material,
the wafer mounting apparatus further includes a heating mechanism that heats the semiconductor wafer,
the method comprises the steps of:
(a) achieving the semiconductor wafer mounting state by mounting the semiconductor wafer on the plurality of lift-up members so that the semiconductor wafer fits in the opening in plan view without being in contact with the ring;
(b) supplying a source gas for epitaxial growth to a front surface of the semiconductor wafer in the semiconductor wafer mounting state; and
(c) heating the semiconductor wafer in the semiconductor wafer mounting state by the heating mechanism, and
after the steps (a) to (c) are performed, an epitaxial layer is formed on a front surface of the semiconductor wafer in the semiconductor wafer mounting state.

17. A semiconductor device comprising:
the epitaxial layer formed by the method of manufacturing a semiconductor device according to claim 16; and
a semiconductor layer for element formation formed in the epitaxial layer.
